(19) United States
(12) Patent Application Publication
(10) Pub. No.: US 2014/0132268 A1
(43) Pub. Date: May 15, 2014

(54) MAGNETIC RESONANCE IMAGING APPARATUS AND IMAGING POSITION SETTING ASSISSTING METHOD

(71) Applicant: (HITACHI MEDICAL CORPORATION, Tokyo (JP)

(72) Inventors: Hisako Nagao, Tokyo (JP); Hiroyuki Itagaki, Tokyo (JP)

(73) Assignee: HITACHI MEDICAL CORPORAITON, Tokyo (JP)

(21) Appl. No.: 14/122,117

(22) PCT Filed: Jun. 22, 2012
(86) PCT No.: PCT/JP2012/066025

§ 371 Date: Nov. 25, 2013

(30) Foreign Application Priority Data
Jun. 24, 2011 (JP) 2011-140971
Mar. 5, 2012 (JP) 2012-047779

(51) Int. Cl. G01R 33/30

(52) U.S. Cl. CPC G01R 33/30
USPC 324/321

(57) ABSTRACT

In order to provide a magnetic resonance imaging apparatus capable of maximizing the effect of an automatic positioning function without increasing the load on an operator even in imaging of an examination part having a plurality of examination sections, when setting an imaging position of an examination part having a plurality of examination sections, automatic positioning processing for automatically detecting all examination sections of the examination part on a scanogram image acquired in advance is performed first. A stack is displayed at a position, which is detected by this automatic positioning processing, on the scanogram image.

### TECHNICAL FIELD

The present invention relates to a technique for assisting the setting of an imaging position in a magnetic resonance imaging (hereinafter, referred to as “MRI”) apparatus.

### BACKGROUND ART

A magnetic resonance imaging (hereinafter, referred to as “MRI”) apparatus is an apparatus that measures a nuclear magnetic resonance (hereinafter, referred to as “NMR” or echo) signal generated by an object, especially, the spins of nuclei that form human tissue, and images the shapes or functions of the head, abdomen, limbs, and the like in a two-dimensional manner or in a three-dimensional manner. Different phase encoding and different frequency encoding are given to NMR signals by the gradient magnetic field, and the NMR signals are measured as time series data. The NMR signals are reconstructed as an image by a two-dimensional or three-dimensional Fourier transform. A region to be imaged is called an imaging slice, and an operator sets the position (imaging position) through a GUI or the like. The imaging position that the operator designates through the GUI or the like is converted into an imaging parameter, and the imaging of the imaging slice is performed. In addition, in this description, an imaging region involving not only an imaging region at the time of single slice imaging but also a three-dimensional region at the time of multi-slice imaging is called an imaging slice hereinafter.

In an examination using the MRI apparatus, normally, a cross-section, which is anatomically determined, of each part to be examined is imaged. This cross-section is called an examination section. Examples of the examination section include an OM line in the case of the head and a meniscus position in the case of the knee. In the examination, the operator sets the imaging position of each object with the examination section as an imaging slice. However, the setting accuracy of the imaging position and the time required depend on the skill of the operator. For example, in a region that is anatomically complex, such as a joint region, considerable expertise is required to set an imaging position such that a part to be examined (for example, cartilage or ligament) is correctly included in the imaging slice.

In order to solve this, a function of automatically setting the imaging position of each examination section of a designated examination part (automatic positioning function) has been proposed (for example, refer to NPL 1). The automatic positioning function disclosed in NPL 1 is to calculate an imaging position on a 3D (three-dimensional) image, which is obtained by 3D volume imaging, using slice plan configuration information obtained by learning the pattern of the imaging position setting that is performed by the operator. It is possible to easily perform the imaging position setting without depending on the skill of the operator. In addition, in order to avoid an increase in time due to 3D volume imaging, a function of determining an imaging position automatically using a 2D scanogram has also been proposed (for example, refer to NPL 2).

### CITATION LIST

### Non Patent Literature

[NPL 1] Kazuaki Nakata et al., “Use Experience of SmartExam” Routine Clinical MRI 2007, Vol. 38 No. 14 P. 55-59, Industrial Development Organization
[NPL 2] Automated Scan Plane Planning for Brain MRI using 2D Scout Images. ISMRM 2010 3136_{—}2971

### SUMMARY OF INVENTION

### Technical Problem

However, the imaging position of the examination section in the actual examination differs depending on a case or the purpose. In particular, in the case of an examination part, such as the spine, there is a plurality of examination sections since there is a plurality of vertebral bodies or intervertebral discs to be imaged. In the case of an examination part having a plurality of examination sections, determination regarding which examination section is to be set as an imaging slice, determination regarding whether or not to increase or decrease the number of imaging slices, and the like are required. Accordingly, adjustment work for the imaging position set by the automatic positioning function is performed.

The adjustment work is performed on a positioning image, but this may have an adverse effect on the time reduction that is an advantage of the automatic positioning function.

The present invention has been made in view of the above-described situation, and it is an object of the present invention to provide a technique for assisting the setting of an imaging position in a magnetic resonance imaging apparatus capable of maximizing the effect of the automatic positioning function without increasing the load on the operator even in the imaging of an examination part having a plurality of examination sections.

### Solution to Problem

In the present invention, when setting the imaging position of an examination part having a plurality of examination sections, automatic positioning processing for automatically detecting all examination sections of the examination part on a scanogram image acquired in advance is performed first. A stack is displayed at a position detected by this automatic positioning processing.

### Advantageous Effects of Invention

According to the present invention, it is possible to provide a magnetic resonance imaging apparatus and an imaging position setting assisting technique that can maximize the effect of the automatic positioning function without increasing the load on the operator even in the imaging of an examination part having a plurality of examination sections.

### BRIEF DESCRIPTION OF DRAWINGS

FIG. 1 is a block diagram showing the overall configuration of an MRI apparatus of a first embodiment.

FIG. 2 is a functional block diagram of a control processing system of the first embodiment.

FIG. 3 is an explanatory view for explaining an example of an output pattern setting screen of the first embodiment.

FIG. 4 is an explanatory view for explaining an example of a detection result display screen of the first embodiment.

FIGS. 5(a) to 5(c) are explanatory views for explaining specific examples of stack display of the first embodiment.

FIGS. 6(a) to 6(c) are explanatory views for explaining specific examples of stack display of the first embodiment.

FIGS. 7(a) to 7(g) are explanatory views for explaining a method of adjusting the output imaging position by an adjustment section of the first embodiment.

FIG. 8(a) is a flow chart of examination processing of the first embodiment, and FIG. 8(b) is a flow chart of stack display processing of the first embodiment.

FIG. 9 is an explanatory view for explaining an example of a protocol setting screen of the first embodiment.

FIG. 10 is an explanatory view for explaining an example of an examination screen of the first embodiment.

FIG. 11 is an explanatory view for explaining another example of the examination screen of the first embodiment.

FIG. 12 is an explanatory view for explaining another example of the examination screen of the first embodiment.

FIG. 13 is an explanatory view for explaining another example of the output pattern setting screen of the embodiment of the present invention.

FIG. 14 is an explanatory view for explaining another example of the examination screen of the first embodiment.

FIGS. 15 (a) to 15(c) are explanatory views for explaining specific examples of the stack display of the first embodiment.

FIG. 16 is an explanatory view for explaining another example of the output pattern setting screen of the first embodiment.

FIGS. 17(a) to 17 (c) are explanatory views for explaining specific examples of the stack display of the first embodiment.

FIG. 18 is a functional block diagram of a control processing system of a second embodiment.

FIG. 19 is an explanatory view for explaining an example of a detection result display screen of the second embodiment.

FIGS. 20(a) to 20(c) are explanatory views for explaining stack display processing of the second embodiment.

FIG. 21 is a flow chart of the stack display processing of the second embodiment.

FIGS. 22 (a) to 22 (c) are explanatory views for explaining the stack display processing of the second embodiment.

FIGS. 23 (a) to 23 (c) are explanatory views for explaining other examples of the stack display processing of the second embodiment.

FIGS. 24 (a) to 24 (c) are explanatory views for explaining other examples of region selection of the second embodiment.

FIGS. 25(a) to 25(d) are explanatory views for explaining modifications of the stack display processing of the second embodiment.

FIGS. 26(a) to 26(d) are explanatory views for explaining modifications of the stack display processing of the second embodiment.

FIGS. 27(a) to 27(d) are explanatory views for explaining modifications of the stack display processing of the second embodiment.

FIGS. 28(a) to 28(c) are explanatory views for explaining a region selection method of the modification of the second embodiment.

FIGS. 29(a) to 29(c) are explanatory views for explaining adjustment processing at the time of multi-imaging of the second embodiment.

### DESCRIPTION OF EMBODIMENTS

Hereinafter, an embodiment to which the present invention is applied will be described.

A magnetic resonance imaging apparatus of the present invention is a magnetic resonance imaging apparatus including: a control processing system that performs calculation and control of an operation of the entire apparatus; and a display device. The control processing system includes an imaging condition setting unit that receives a setting for performing an examination, an imaging position setting unit that sets an imaging position, and an imaging unit that images the imaging position set by the imaging position setting unit. The imaging position setting unit includes an automatic positioning section that detects positions of all examination sections of an examination part, which is received by the imaging condition setting unit, on a scanogram image acquired in advance and a detection result display section that displays the scanogram image on the display device and that sets one or more positions determined in advance, among the positions detected by the automatic positioning section, as the imaging positions and displays a stack at the imaging positions on the scanogram image.

In addition, the imaging position setting unit further includes an output pattern setting section that sets the examination sections, which are set as the imaging positions, as output patterns. The one or more positions determined in advance are positions of the examination sections, which are set as the output patterns, among the positions detected by the automatic positioning section.

In addition, the output pattern setting section generates an output pattern setting screen corresponding to the received examination part, displays the output pattern setting screen on the display device, and receives a setting of the output examination section through the output pattern setting screen.

In addition, a data storage unit that stores selectable examination sections as output patterns in advance for each examination part is further provided. The output pattern setting section receives the setting of the output examination section by receiving a selection from the output patterns stored in the data storage unit.

In addition, each examination section includes one or more slices, and the detection result display section displays an outer frame of a range, which is specified by all slices of each of the examination sections that are output, as the stack.

In addition, the detection result display section displays the stack so as to blink.

In addition, the detection result display section switches display and non-display of the stack according to an instruction from an operator or at time intervals set in advance.

In addition, there is a plurality of examination sections set as the output patterns, and the detection result display section displays the stack in a different display form for each examination section.

In addition, in the magnetic resonance imaging apparatus, the detection result display section includes a selection receiving section that receives a selection of a position set as the imaging position.

In addition, an input device that receives an input from an operator is further provided. The detection result display section performs a simple display at a position, which is detected by the automatic positioning section, on the scanogram image. The selection receiving section receives a selection of the position by receiving a selection of the simple display through the input device. The simple display is a display in which there is no interference with visibility of the scanogram image and a position and an inclination of the detected examination section are understandable.

In addition, the imaging position setting unit further includes an output pattern setting section that sets the examination sections, which are set as the imaging positions, as output patterns. The detection result display section performs a simple display at a position of an examination section set as the output pattern, among the positions detected by the automatic positioning section, on the scanogram image. The selection receiving section receives a selection of the position by receiving a selection of the simple display through the input device. The simple display is a display in which there is no interference with visibility of the scanogram image and the position and the inclination of the detected examination section are understandable.

In addition, an input device that receives an input from an operator is further provided. The selection receiving section receives a selection of a region on the scanogram image through the input device and sets a position within the selected region, among the positions detected by the automatic positioning section, as the selected position.

In addition, the imaging position setting unit further includes an output pattern setting section that sets the examination section, which is set as the imaging position, as an output pattern. The selection receiving section receives a selection of a region on the scanogram image through the input device and sets a position within the selected region, which is a position of the examination section set as the output pattern among the positions detected by the automatic positioning section, as the selected position.

In addition, the imaging position setting unit further includes an adjustment section that adjusts the imaging position set by the detection result display section, and the imaging unit images the imaging position after the adjustment.

In addition, the adjustment section displays adjustment instruction buttons, which are used for adjustment of the imaging position, on the display device together with the stack displayed by the detection result display section and receives an adjustment of the imaging position through the adjustment instruction buttons.

In addition, an input device that receives an instruction from an operator is further provided. The adjustment section performs an adjustment by updating at least one of a display position of the stack and the number of stacks according to an instruction from the operator with respect to the stack through the input device.

In addition, each of the examination sections includes one or more slices, and the adjustment section receives a change of the number of slices of the examination section according to an instruction from the operator with respect to the stack.

In addition, the adjustment instruction buttons include a button for giving an instruction regarding a movement direction of the stack selected by the operator and a button forgiving an instruction regarding an arrangement of the stack selected by the operator.

In addition, an imaging position setting assisting method of the present invention is an imaging position setting assisting method for assisting a setting of an imaging position of an examination part having a plurality of examination sections in a magnetic resonance imaging apparatus including a control processing system that performs calculation and control of an operation of the entire apparatus. The imaging position setting assisting method includes: an automatic positioning step in which the control processing system detects positions of all examination sections of the examination part on a scanogram image acquired in advance; and a detection result display step in which the control processing system sets one or more positions, which are determined in advance among the detected positions, as the imaging positions, and displays a stack at the imaging position of the scanogram image while ensuring visibility.

### First Embodiment

Hereinafter, a first embodiment to which the present invention is applied will be described. Hereinafter, in all diagrams illustrating the embodiments of the present invention, the same reference numerals are given to elements having the same functions, and repeated explanation thereof will be omitted.

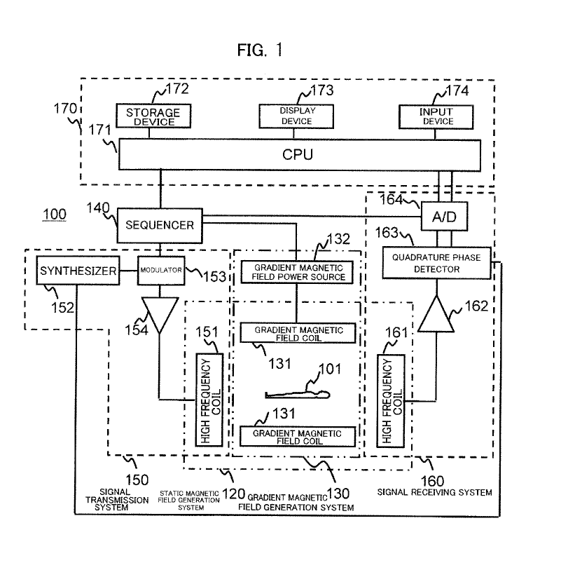

First, a complete overview of an example of an MRI apparatus of the present embodiment will be given. FIG. 1 is a block diagram showing the overall configuration of an MRI apparatus 100 of the present embodiment. The MRI apparatus 100 of the present embodiment acquires a tomographic image of an object using an NMR phenomenon. As shown in FIG. 1, the MRI apparatus 100 includes a static magnetic field generation system 120, a gradient magnetic field generation system 130, a signal transmission system 150, a signal receiving system 160, a control processing system 170, and a sequencer 140.

The static magnetic field generation system 120 generates a uniform static magnetic field in space around an object 101 in a direction perpendicular to the body axis in the case of a vertical magnetic field method and in the body axis direction in the case of a horizontal magnetic field method, and includes a permanent magnet type, normal conduction type, or superconducting type static magnetic field generator disposed around the object 101.

The gradient magnetic field generation system 130 includes gradient magnetic field coils 131 wound in three axial directions of X, Y, and Z, which are the coordinate system (stationary coordinate system) of the MRI apparatus 100, and a gradient magnetic field power source 132 that drives each gradient magnetic field coil, and applies gradient magnetic fields Gx, Gy, and Gz in the three axial directions of X, Y, and Z by driving the gradient magnetic field power source 132 of each gradient magnetic field coil 131 according to a command from the sequencer 140 to be described later.

The signal transmission system 150 emits a high frequency magnetic field pulse (hereinafter, referred to as an “RE pulse”) to the object 101 in order to cause nuclear magnetic resonance in the nuclear spins of atoms that form the body tissue of the object 101, and includes a high frequency oscillator (synthesizer) 152, a modulator 153, a high frequency amplifier 154, and a transmission-side high frequency coil (transmission coil) 151. The high frequency oscillator 152 generates an RF pulse, and outputs the RF pulse at the timing according to a command from the sequencer 140. The modulator 153 performs amplitude modulation of the output RF pulse, and the high frequency amplifier 154 amplifies the amplitude-modulated RF pulse and supplies it to the transmission coil 151 disposed near the object 101. The transmission coil 151 emits the supplied RF pulse to the object 101.

The signal receiving system 160 detects a nuclear magnetic resonance signal (an echo signal, an NMR signal) emitted by the nuclear magnetic resonance of the nuclear spins, which form the body tissue of the object 101, and includes a receiving-side high frequency coil (receiving coil) 161, a signal amplifier 162, a quadrature phase detector 163, and an A/D converter 164. The receiving coil 161 is disposed near the object 101, and detects an NMR signal of the response from the object 101 that is induced by the electromagnetic wave emitted from the transmission coil 151. The detected NMR signal is amplified by the signal amplifier 162 and is then divided into two orthogonal signals by the quadrature phase detector 163 at the timing according to the command from the sequencer 140. Each of the orthogonal signals is converted into the digital amount by the A/D converter 164 and is transmitted to the control processing system 170.

The sequencer 140 applies an RF pulse and a gradient magnetic field pulse repeatedly according to a predetermined pulse sequence. In addition, the pulse sequence describes the timing or the strength of a high frequency magnetic field, a gradient magnetic field, and signal reception, and is stored in advance in the control processing system 170. The sequencer 140 operates according to the instruction from the control processing system 170, and transmits various commands, which are required for data collection of a tomographic image of the object 101, to the signal transmission system 150, the gradient magnetic field generation system 130, and the signal receiving system 160.

The control processing system 170 performs overall control of the MRI apparatus 100, various operations such as data processing, display and storage of processing results, and the like, and includes a CPU 171, a storage device 172, a display device 173, and an input device 174. The storage device 172 is formed by an external storage device, such as a hard disk, an optical disc, and a magnetic disk. The display device 173 is a CRT, a liquid crystal display device, or the like. The input device 174 is an interface for the input of various kinds of control information of the MRI apparatus 100 or control information of processing performed in the control processing system 170. For example, the input device 174 includes a track ball, a mouse, and a keyboard. The input device 174 is disposed near the display device 173. The operator interactively inputs instructions and data, which are required for various kinds of processing of the MRI apparatus 100, through the input device 174 while observing the display device 173.

The CPU 171 realizes the control of the operation of the MRI apparatus 100 and each process, such as various kinds of data processing, of the control processing system 170 by executing a program stored in advance in the storage device 172 according to the instruction input by the operator. For example, when the data from the signal receiving system 160 is input to the control processing system 170, the CPU 171 executes processing, such as signal processing and image reconstruction, and displays a tomographic image of the object 101, which is the result, on the display device 173 and also records it in the storage device 172.

The transmission coil 151 and the gradient magnetic field coils 131 are provided in the static magnetic field space of the static magnetic field generation system 120, into which the object 101 is inserted, so as to face the object 101 in the case of the vertical magnetic field method and so as to surround the object 101 in the case of the horizontal magnetic field method. In addition, the receiving coil 161 is provided so as to face or surround the object 101.

Currently, a nuclide imaged by an MRI apparatus, which is widely used clinically, is a hydrogen nucleus (proton) that is a main constituent material of the object 101. In the MRI apparatus 100, the shapes or functions of the head, abdomen, limbs, and the like of the human body are imaged in a two-dimensional or three-dimensional manner by imaging information regarding the spatial distribution of the proton density or the spatial distribution of the relaxation time of the excited state.

The imaging procedure of the MRI apparatus 100 is as follows. First, an instruction is output to the signal transmission system 150 according to the pulse sequence, and an RE′ pulse is emitted from the transmission coil 151 to the object 101. To the echo signal generated from the object 101 by the irradiation of the RF pulse, different phase encodings are given by the gradient magnetic field. As the number of phase encodings, a value of 128, 256, 512, or the like per image is usually selected. The receiving coil 161 detects each echo signal. The echo signal is usually detected as a time-series signal of 128, 256, 512, or 1024 pieces of sampling data. These pieces of data are transmitted from the signal receiving system 160 to the control processing system 170. Then, image processing, such as a two-dimensional Fourier transform, is performed by the control processing system 170. As a result, one reconstructed image is generated.

The above-described imaging is performed at each imaging position set as an imaging slice. The imaging position is specified using a coordinate system (referred to as apparatus coordinates) set in advance in the MRI apparatus 100, for example. In the MRI apparatus 100, the imaging of the cross-section of the specified imaging positron is realized by adjusting a slice selection gradient magnetic field and the irradiation frequency of the RE pulse.

In the present embodiment, in the examination of an examination part having a plurality of examination sections, the imaging position of a desired examination section is determined using an automatic positioning function, and imaging is performed. In this case, adjustment work caused by the plurality of examination sections becomes easy.

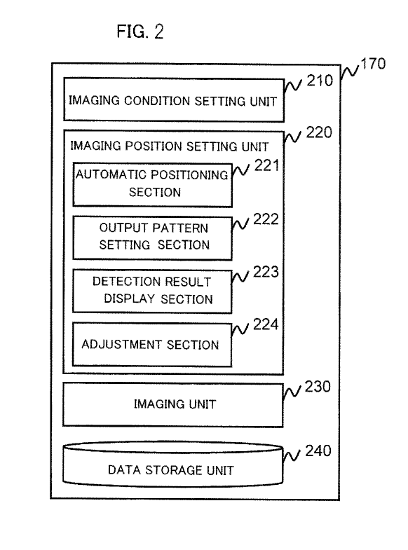

In order to realize this, as shown in FIG. 2, the control processing system 170 of the present embodiment includes an imaging condition setting unit 210 that receives various kinds of settings for performing an examination, such as an imaging parameter (scan parameter), an imaging position setting unit 220 that sets an imaging position, an imaging unit 230 that executes main imaging of the imaging position set by the imaging position setting unit 220, and a data storage unit 240 that stores data used for these processes, various kinds of data obtained during the processes, and processing results. In addition, the imaging parameters received by the imaging condition setting unit 210 include an examination part and the number of stacks.

The imaging position setting unit 220 includes: an automatic positioning section 221 that automatically detects the imaging positions of all examination sections of a designated examination part; an output pattern setting section 222 that generates an output pattern setting screen corresponding to the designated examination part, receives the designation of an examination section, which is desired as an automatic positioning output, from an operator through the output pattern setting screen, and sets it as an output pattern; a detection result display section 223 that sets a position corresponding to the examination section set by the output pattern setting section 222, among the imaging positions detected by the automatic positioning section 221, as an output imaging position and displays a stack at the output imaging position in a state where the visibility is ensured; and an adjustment section 224 that assists the adjustment of the output imaging position.

The data storage unit 240 is built in the storage device 172, and other functions of the control processing system 170 are realized when the CPU 171 loads a program stored in the storage device 172 to the memory and executes it.

The automatic positioning section 221 calculates automatically the position (imaging position) of an imaging slice, which corresponds to each examination section, of an examination part designated by the operator using a known method disclosed in NPL 1 or NPL 2 or the like. When an instruction of start is received, the automatic positioning section 221 performs scanogram imaging to detect the imaging position of the examination part on the obtained scanogram image. The position information of the detected imaging position is stored in the data storage unit 240 for each imaging position as described above.

In the present embodiment, a stack is displayed at only the imaging position used in main imaging of the imaging positions detected by the automatic positioning section 221. The imaging position at which a stack is displayed is set as an output pattern by the output pattern setting section 222. Designation is received by specifying an examination section. As described above, the automatic positioning section 221 detects the imaging positions of all examination sections that the examination part has. In addition, the automatic positioning section 221 may be configured to detect only the cross-section designated as an examination section.

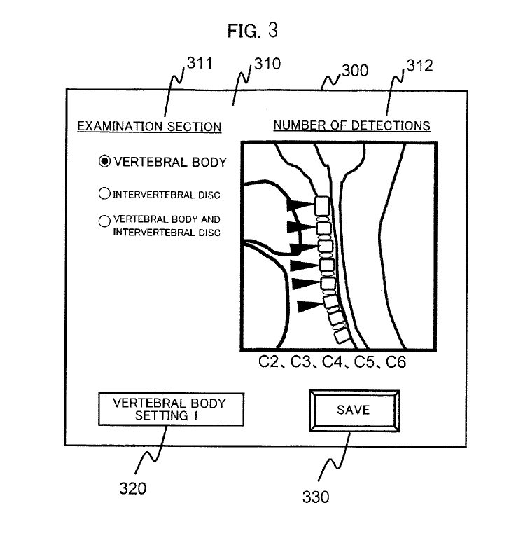

The output pattern setting section 222 generates an output pattern setting screen corresponding to the examination part, displays the output pattern setting screen on the display device 173, and receives an instruction from the operator. FIG. 3 shows an example of an output pattern setting screen 300 displayed when the examination part is a spine region. As shown in this diagram, the output pattern setting screen 300 includes an output pattern setting region 310, an output pattern name setting region 320, and a save button 330.

The output pattern setting region 310 receives the selection of an examination section from the imaging positions detected by the automatic positioning section 221. For this reason, the output pattern setting region 310 includes an examination section setting region 311 to receive the setting of an examination section. In addition, some examination sections may have a plurality of imaging positions. In this case, the setting of the number of detections is also received. Therefore, a number-of-detections setting region 312 to receive the setting of the number of detections is further included.

The operator selects an examination section through the examination section setting region 311. In the examination section setting region 311, information (examination section information) for specifying the examination section of the examination part is displayed, for example, in a display form, such as a radio button and a pull-down menu, so as to be selectable. The examination section information displayed in the examination section setting region 311 and the image displayed in the number-of-detections setting region 312 are stored in the data storage unit 240 in advance so as to match the examination part. The image displayed in the number-of-detections setting region 312 is assumed to be a standard image of the examination part.

In the case of imaging an axial (AX) cross-section when the examination parties spine region, an examination target is the vertebral body or the intervertebral disc. When the spine region is set as an examination part, the automatic positioning section 221 detects automatically, as the examination sections, imaging positions of both a surface parallel to the vertebral body including the vertebral body (vertebral body surface) and a surface parallel to the intervertebral disc including the intervertebral disc (intervertebral disc surface). From these surfaces, the operator selects, as the examination section, the vertebral body surface, the intervertebral disc surface, or both of the vertebral body surface and the intervertebral disc surface.

In addition, there are a plurality of vertebral bodies and a plurality of intervertebral discs. Accordingly, when further narrowing the imaging range, the operator selects the imaging range by setting the number of detections of examination sections in the number-of-detections setting region.

The output pattern name setting region 320 is a region for inputting and setting the information specifying the output pattern set in the output pattern setting region 310. By pressing the save button 330, the output pattern set in the output pattern setting region 310 is registered in the data storage unit 240 so as to match the output pattern name set in the output pattern name setting region 320.

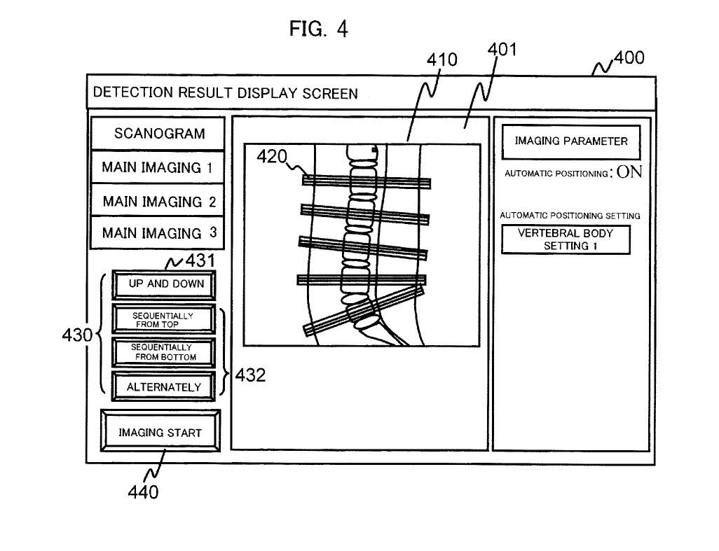

When the automatic positioning section 221 performs positioning processing, the detection result display section 223 displays the result on a positioning image displayed on a detection result display screen to be described. FIG. 4 shows an example of a detection result display screen 400. The detection result display screen 400 is generated by the imaging position setting unit 220 using the data stored in the data storage unit 240, and is displayed on the display device 173.

As shown in FIG. 4, the detection result display screen 400 includes a display region 401 where a positioning image 410 is displayed, an adjustment instruction region 430 where various buttons used for the adjustment of the output imaging position are displayed, and an imaging start button 440 for receiving the intention to determine the output imaging position and the instruction to start imaging.

The detection result display section 223 displays a stack 420 at the output imaging position on the positioning image 410. The stack 420 is displayed in a display form in which the visibility of the positioning image 410 can be ensured. That is, the stack 420 is displayed in a display form in which the structure of the examination part and the state of tissue in the positioning image 410 can be checked. In addition, the detection result display screen 400 may be generated by the detection result display section 223 and displayed on the display device 173 in response to the result of the positioning processing.

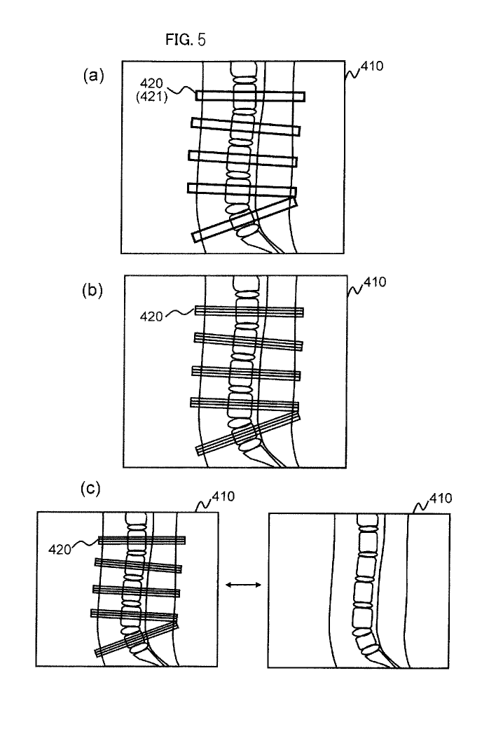

FIGS. 5(a) to 5(c) show specific examples of the stack 420 that is displayed on the positioning image 410 by the detection result display section 223. Here, a case where the examination part is a spine region is illustrated.

FIG. 5(a) is an example in which an output imaging position including a plurality of slices, which form an examination section, is set as an imaging range for each examination section and only an outer frame 421 of the rectangle is displayed as the stack 420. A rectangular region showing the imaging range is calculated from the output imaging position and from the number of slices and a distance between slices that are set by the imaging parameters.

FIG. 5(b) is an example in which the stack 420 is displayed at the output imaging position so as to blink. All of a plurality of slices that form the examination section are displayed so as to blink. In addition, FIG. 5(c) is an example in which the display/non-display of the stack 420 is controlled according to the instruction from the operator. Here, the operator controls the display/non-display, for example, by designating the stack 420 at the output imaging position that the operator desires to change the display/non-display using the input device 174, such as a mouse. The display/non-display of the stack 420 at all output imaging positions may be controlled at a time by the instruction from the operator. In addition, the display/non-display of the stack 420 may be automatically performed alternately by the instruction from the operator or at time intervals set in advance.

In addition, it is also possible to adopt a configuration in which the operator can select a display form of the stack 420 using the plurality of display forms shown in FIGS. 5 (a) to 5 (c). For example, the output pattern setting screen 300 includes a region for selecting a display form, and the operator selects a display form through the output pattern setting screen 300. The detection result display section 223 displays the stack 920 according to the selection of the operator. In addition, when there is a plurality of examination sections set as an output pattern, the detection result display section 223 may change the display form for each examination section.

In addition, the number of imaging positions (the number of designated stacks) designated as an imaging parameter may be different from the number of output imaging positions. The display of the stack 420 by the detection result display section 223 in such a case will be described.

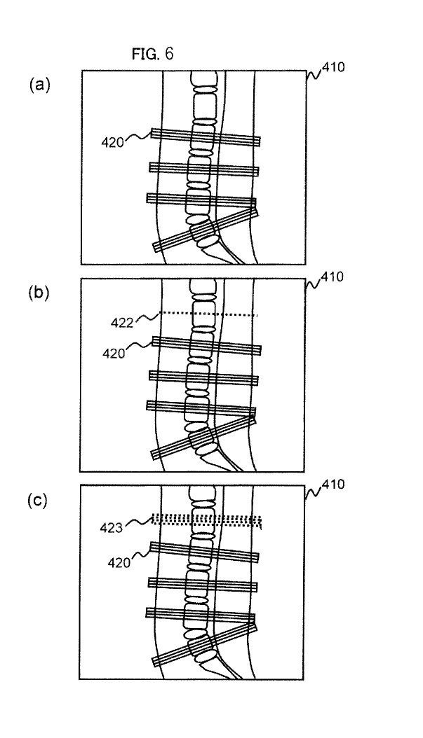

FIGS. 6(a) to 6(c) are diagrams for explaining a display method of the stack 420 for each relationship between the number of designated stacks and the number of output imaging positions.

FIG. 6(a) is a case where the number of designated stacks is the same as the number of output imaging positions. In this case, the stack 420 is displayed at each output imaging position. That is, the stack 420 is displayed by the number of designated stacks.

FIG. 6(b) is a case where the number of designated stacks is smaller than the number of output imaging positions (the number of designated stacks<the number of output imaging positions). For example, in the case of the vertebral body, the stack 420 is displayed at each output imaging position by the number of designated stacks in centric order toward the output imaging position of the end alternately from the output imaging position of the center in the vertical direction (body axis direction). In addition, display of a different display form from the stack 420 is performed at the remaining output imaging positions. This display is called a surplus stack 422. For example, the surplus stack 422 is displayed in a dotted line, a different color from the stack 420, or the like.

FIG. 6(c) is a case where the number of designated stacks is larger than the number of output imaging positions (the number of designated stacks>the number of output imaging positions). For example, in the case of the vertebral body, the stack 420 is displayed at each output imaging position by the number of output imaging positions centrically from the output imaging position at the center in the vertical direction (body axis direction). In addition, display of a different display form from the stack 420 is performed in parallel to the stack 420 at the end by the designated number of remaining stacks. This display is called an insufficiency stack 423. For example, the insufficiency stack 423 is displayed in a dotted line, a different color from the stack 420, or the like. In addition, the insufficiency stack 423 is displayed at a position, which is spaced by the average distance of the distances between the respective imaging positions, centrically so as to continue to the stack 420.

The adjustment section 224 assists the adjustment of the output imaging position by the operator. The assistance is performed on the detection result display screen 400. The adjustment section 224 performs the assistance when receiving an instruction, such as the selection, movement, and deletion of the stack 420 and the resetting of an output imaging position, from the operator through the detection result display screen 400 and the input device 174. The selection of the stack 420 is performed, for example, by an operation of clicking a mouse button in a state where the mouse button overlaps the stack 420 to be selected or an operation of designating a region of a predetermined shape including the stack 420 to be selected. In addition, whenever the operation, such as movement, deletion, and resetting, is performed, the position information of each imaging position registered in the data storage unit 240 is updated. An example of the assistance when the number of designated stacks is different from the number of output imaging positions is shown.

For example, when the number of designated stacks is larger than the number of output imaging positions, the insufficiency stack 423 is displayed as shown in FIG. 6(c). When there is a clearly unnecessary stack, the operator selects the unnecessary insufficiency stack 423 and instructs the deletion of the unnecessary insufficiency stack 423. The adjustment section 224 deletes the insufficiency stack 423 designated to be deleted by the operator. In this case, the adjustment section 224 also reduces the number of designated stacks, which is set by the imaging parameter, by the number of designated stacks that have been deleted. In addition, when there is a position which has not been detected but is to be imaged actually, the operator moves the insufficiency stack 423 to the position. When such an operation is received from the operator, the adjustment section 224 sets the designated position as a new output imaging position, and displays the stack 420 at the position.

For example, when the number of designated stacks is smaller than the number of output imaging positions, the surplus stack 422 is displayed as shown in FIG. 6(b). When the operator wants to change the imaging position without changing the number of designated stacks, the operator selects the stack 420, which is displayed at a position where imaging does not need to be performed, and moves it to a desired imaging position. When such an instruction is received, the adjustment section 224 displays the stack 420 at the output imaging position after the movement, and displays the surplus stack 422 at the position before the movement.

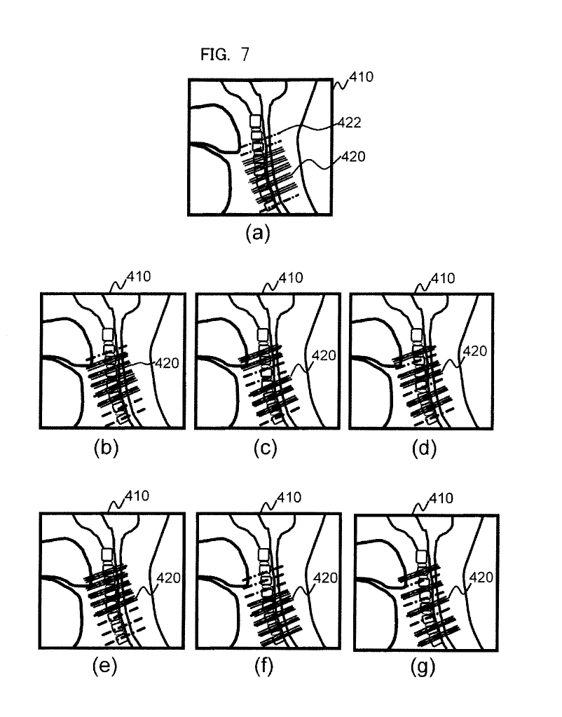

A specific operation method when the number of designated stacks is smaller than the number of output imaging positions will be described with reference to FIG. 7. FIG. 7(a) shows a state where the stack 420 and the surplus stack 422 before adjustment are displayed. The adjustment section 224 receives an instruction of adjustment using position adjustment instruction buttons, such as a movement direction instruction button (up-and-down button) 431 and an arrangement instruction button (button for sequential arrangement from top, button for sequential arrangement from bottom, and button for alternate arrangement) 432, which are arranged in the adjustment instruction region 430 of the detection result display screen 400, and assists the adjustment of the output imaging position.

For example, FIG. 7(b) shows processing when moving all stacks 420 up and down. The operator selects all stacks 420, and presses the movement direction instruction button (up-and-down button) 431. In response to this, the adjustment section 224 sets the output imaging positions of both ends as upper and lower limits, and moves all stacks 420 up and down between the upper and lower limits so as to match each output imaging position.

For example, FIG. 7(c) shows the process when moving the selected stack 420 up and down. The operator selects the arbitrary stack 420 to be moved, and presses the movement direction instruction button (up-and-down button) 431. In response to this, the adjustment section 224 sets the output imaging positions of both ends as upper and lower limits, and moves the selected stack 420 up and down between the upper and lower limits so as to match each output imaging position. In this case, when the stack 420 is already placed at the output imaging position of the movement destination, the selected stack is moved skipping the output imaging position.

For example, FIG. 7(d) shows processing when moving the selected stack 420 to a desired output imaging position. The operator selects the arbitrary stack 420 to be moved, and moves the selected stack 420 to an output imaging position where the stack 420 is not placed. The selection and the movement are performed by clicking and dragging operations of the input device 174, such as a mouse, for example. The adjustment section 224 moves the selected stack 420 to the output imaging position of the movement destination.

For example, FIGS. 7(e) and 7(f) show processing when placing the stacks 420 sequentially from the imaging position of one of the ends for each of the detected imaging positions. The operator gives an instruction by pressing the button for sequential arrangement from top or the button for sequential arrangement from bottom of the arrangement instruction button 432. When receiving the instruction by these buttons, the adjustment section 224 displays the stack 420 at the output imaging position according to the instruction.

For example, FIG. 7(g) shows processing when placing the stack 420 alternately at a plurality of detected imaging positions. The operator gives an instruction by pressing the button for alternate arrangement of the arrangement instruction button 432. When receiving the instruction by this button, the adjustment section 224 displays the stack 420 at the output imaging position according to the instruction. For example, the stack 420 is displayed at each output imaging position alternately and centrically from the output imaging position of the center in the vertical direction.

Using the method exemplified above, the adjustment section 224 assists the adjustment of stack arrangement by the operator. The operator can easily move each stack 420 to the output imaging position on the detection result display screen 400 by pressing a button prepared in advance or using a mouse that is a normal operation interface, for example.

Also when the number of designated stacks is the same as the number of output imaging positions, the operator may perform an adjustment, such as adjusting the position of the stack 420, decreasing or increasing the number of designated stacks, or aligning the stacks 420, after checking the position on the positioning image. The adjustment section 224 also assists such adjustment.

For example, when the position or the angle of the stack 420 needs to be adjusted, the operator moves the stack 420 to be adjusted to a desired position by mouse dragging. When such an instruction is received, the adjustment section 224 displays the stack 420 at a position after the movement (output imaging position). In addition, it is also possible to prepare a button for receiving an instruction to return the display position of the stack 420 to the position before the movement by mouse dragging from the position after the movement, a special clicking operation, and the like.

In addition, when the number of designated stacks needs to be reduced, the operator reduces the number of designated stacks of the imaging parameter, and designates the desired stack 420 by the number of reduced stacks by a mouse click or the like. When such an instruction is received, the adjustment section 224 deletes the display of the stack 420 at the output imaging position designated by the mouse click. In addition, it is also possible to prepare a button for receiving an instruction to delete the display of the selected stack 420. In addition, the processing for reducing the number of designated stacks of the imaging parameter may be automatically performed. That is, the number of designated stacks of the imaging parameter may be reduced by the number of stacks 420 deleted by the operator so as to be interlinked with the number of stacks 420 displayed.

In addition, when the number of designated stacks needs to be increased, the operator increases the number of designated stacks of the imaging parameter and performs line drawing at a position, at which the stack 420 needs to be placed, on the positioning image. When such an instruction is received, the adjustment section 224 sets the position of line drawing as an output imaging position and displays the stack 420 there. In addition, the processing for increasing the number of designated stacks of the imaging parameter may be automatically performed. That is, the number of designated stacks of the imaging parameter may be increased by the number of stacks 420 increased by the operator so as to be interlinked with the number of stacks 420 displayed.

In addition, when the stacks 420 need to be aligned, the operator designates a line passing through the center of each stack 420 on the positioning image. The line to be designated is a line along the spinal column, for example. When such an instruction is received, the adjustment section 224 performs re-display by changing the display position of each stack 420 so that the center comes to the line designated by the operator. In addition, when only the specific stack 420 needs to be moved and aligned, the operator designates a position, which should be the center of the stack 420, on the stack 420 to be moved on the positioning image by a mouse click or the like. When such an instruction is received, the adjustment section 224 performs re-display by moving the stack 420 to the position designated by the operator so that the center comes to the position.

In addition, when an instruction to start imaging by the imaging start button 440 on the detection result display screen 400 is received, the imaging position setting unit 220 sets the output imaging position, at which the stack 420 is displayed at that point in time, as an imaging position in main imaging. Then, using the information of each output imaging position stored in the data storage unit 240, an imaging parameter is calculated so that imaging is performed at the imaging position.

Using the imaging parameter set by the operator and the imaging parameter calculated by the imaging position setting unit 220, the imaging unit 230 issues a command to the sequencer 140 according to the pulse sequence to perform imaging.

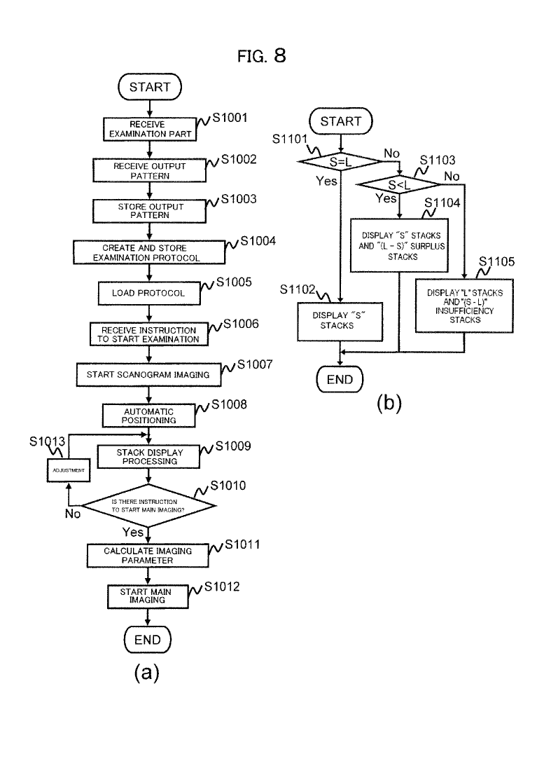

Next, the flow of examination of the present embodiment according to each of the above functions will be described. FIG. 8(a) is a process flow at the time of examination of the present embodiment.

First, the imaging condition setting unit 210 receives an examination part (step S1001). Then, the output pattern setting section 222 displays the output pattern setting screen 300 for receiving the setting of the output pattern of the received examination part on the display device 173, and receives the setting of the output pattern from the operator (step S1002). Then, the setting of the output pattern name is received, and the output pattern is stored in the data storage unit 240 so as to match the output pattern name (step S1003).

Then, the imaging condition setting unit 210 creates and stores an examination protocol (step S1004). Here, the examination protocol is a collection of a plurality of imagings, which are included in an examination, according to the examination procedure. A common examination protocol includes a scanogram imaging for acquiring a positioning image and a main imaging for acquiring a diagnostic image. The automatic positioning section 221 detects an imaging position using the positioning image acquired by the scanogram imaging. In addition, when there is one imaging position, main imaging is performed at the imaging position determined by the automatic positioning section 221.

When creating an examination protocol, the imaging condition setting unit 210 displays a protocol setting screen 500 on the display device 173, and receives a setting required for examination protocol creation through the protocol setting screen 500.

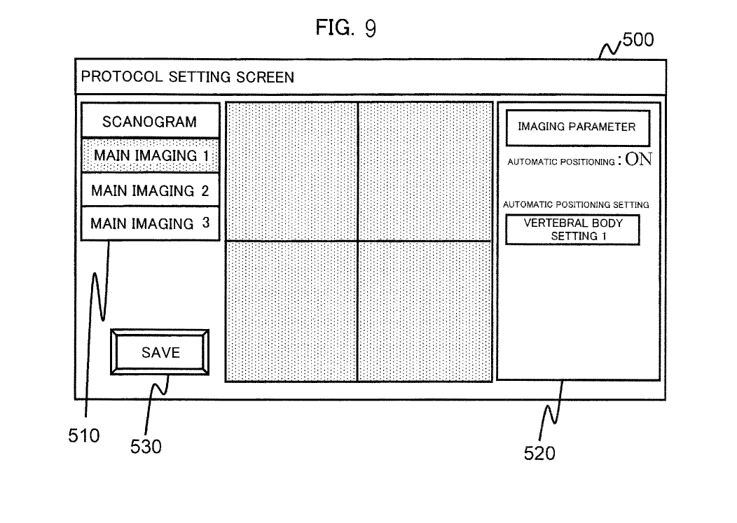

FIG. 9 shows an example of the protocol setting screen 500. As shown in this diagram, the protocol setting screen 500 receives the setting of the imaging parameter for each imaging performed in examinations, such as the scanogram imaging and the main imaging. An imaging type setting region 510 for receiving the setting of imaging to be performed, a parameter setting region 520 for receiving the setting of the imaging parameter for each imaging, and a save button 530 are provided. In the present embodiment, in the scanogram imaging, in addition to the imaging parameter, a setting regarding whether or not to perform automatic positioning is received. When the setting for performing automatic positioning is received, a name stored in step S1003 is displayed as the output pattern.

The imaging condition setting unit 210 stores the content of the setting, which has been received through the protocol setting screen 500, in the data storage unit 240 as an examination protocol in response to the pressing of the save button 530. At the time of storage, the setting of the examination protocol name is received.

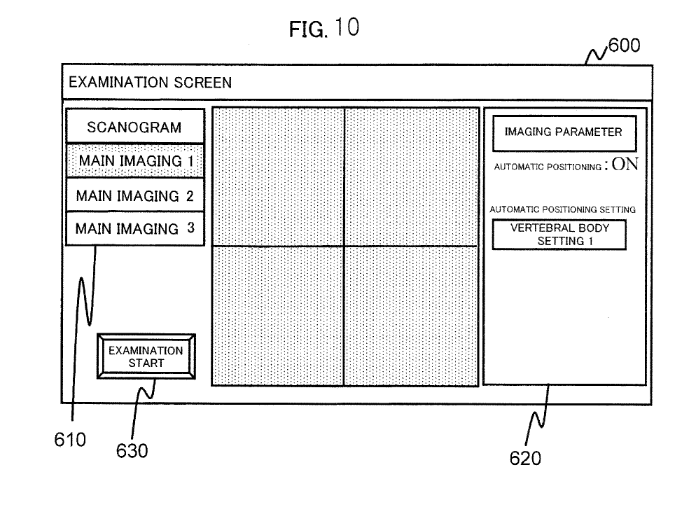

Then, the imaging condition setting unit 210 displays an examination screen 600 shown in FIG. 10 on the display device 173, and loads the protocol stored in step S1004 (step S1005). As shown in FIG. 10, an imaging type display region 610 where the type of imaging performed in an examination is displayed, a parameter display region 620 where an imaging parameter for each imaging type is displayed, and an examination start button 630 for receiving an instruction to start an examination are displayed on the examination screen 600. The operator checks the display content, and presses the examination start button 630.

In response to the pressing of the examination start button 630 by the operator (step S1006), the imaging unit 230 starts an imaging for the examination. In the present embodiment, a scanogram imaging is started first (step S1007). Then, after the scanogram imaging is ended and a scanogram image is obtained, the automatic positioning section 221 performs automatic positioning (step S1008). After the end of the automatic positioning processing, the detection result display section 223 performs stack display processing for displaying the stack 420 on the detection result display screen 400 (step S1009).

Here, the stack display processing of the detection result display section 223 of the present embodiment will be described. FIG. 8(b) shows the flow of the stack display processing of the present embodiment. As described in FIGS. 6(a) to 6(c), the number of designated stacks S is first compared with the number of output imaging positions L (steps S1101 and S1103). When the number of designated stacks S is the same as the number of output imaging positions L, the stack 420 is displayed at each output imaging position (step S1102). In this case, “S” stacks 420 are displayed.

On the other hand, when the number of designated stacks S is smaller than the number of output imaging positions L, the stacks 420 of the number of designated stacks S are displayed at predetermined output imaging positions and the “(L−S)” surplus stacks 422 are displayed at the remaining output imaging positions as shown in FIG. 6(b) (step S1104).

In addition, when the number of designated stacks S is larger than the number of output imaging positions, the stacks 420 of the number of output imaging positions L are displayed at each output imaging position and the remaining “(S−L)” insufficiency stacks 423 are displayed at predetermined positions as shown in FIG. 6(c) (step S1105).

After the end of the stack display processing, the imaging position setting unit 220 waits for an instruction to start main imaging from the operator through the detection result display screen 400 (step S1010). When an instruction to start main imaging is received, the imaging position setting unit 220 calculates an imaging parameter so that the output imaging position where the stack 420 is displayed at that point in time is set as the imaging position of the main imaging (step S1011). Then, the imaging unit 230 starts the main imaging using the calculated imaging parameter (step S1012).

On the other hand, when an instruction of adjustment, such as an instruction of selection or an instruction of movement, is received before the instruction to start main imaging in step S1010, the adjustment section 224 adjusts the display position of the stack 420 according to the received instruction using the above-described method (step S1013). Then, the imaging position setting unit 220 proceeds to step S1010 and waits for an instruction to start main imaging.

In addition, the adjustment of the adjustment section 224 in step S1013 is performed according to the instruction from the operator as described previously. In addition, when the number of designated stacks is smaller than the number of output imaging positions, adjustment is assisted using the method shown in FIGS. 7(a) to 7(g).

The control processing system 170 of the present embodiment performs an examination in the procedure described above.

As described above, the MRI apparatus 100 of the present embodiment is the MRI apparatus 100 including the control processing system 170, which performs calculation and control of the operation of the entire apparatus, and the display device 173. The control processing system 170 includes the imaging condition setting unit 210 that receives a setting for performing an examination, the imaging position setting unit 220 that sets an imaging position, and the imaging unit 230 that images the imaging position set by the imaging position setting unit 220. The imaging position setting unit 220 includes the automatic positioning section 221 that detects the positions of all examination sections of the examination part, which is received by the imaging condition setting unit 220, on the scanogram image acquired in advance and the detection result display section 223 that displays the scanogram image on the display device 173 and that sets one or more positions determined in advance, among the positions detected by the automatic positioning section 221, as the imaging positions and displays the stack 420 at the imaging positions on the scanogram image while ensuring visibility.

In addition, the imaging position setting unit 221 may further include the output pattern setting section 222 that sets the examination section, which is set as the imaging position, as an output pattern. The one or more positions determined in advance may be the positions of examination sections, which are set as the output pattern, among the positions detected by the automatic positioning section 221. In addition, the output pattern setting section 222 may generate the output pattern setting screen 300 according to the received examination part and display it on the display device 173, and may receive the setting of the examination section output through the output pattern setting screen 300.

In this case, each examination section may include one or more slices, and the detection result display section 223 may be configured to display the outer frame of the range, which is specified in all slices of the examination sections that are output, as the stack 420. In addition, the detection result display section 223 may be configured such that the stack 420 is displayed so as to blink. In addition, the detection result display section 223 may be configured to switch the display and non-display of the stack 420 according to the instruction from the operator or at time intervals set in advance. In addition, the detection result display section 223 may be configured to display the stack 420 in a different display form for each examination section when there is a plurality of examination sections set as the output pattern.

In addition, the imaging position setting unit 220 may further include the adjustment section 224 that adjusts the imaging position set by the detection result display section, and the imaging unit 230 may be configured to perform imaging of the imaging position after the adjustment. In this case, the adjustment section 224 may be configured to display adjustment instruction buttons, which are used to adjust the imaging position, on the display device 173 together with the stack 420 displayed by the detection result display section 223 and to receive the adjustment of the imaging position through the adjustment instruction buttons. In addition, the adjustment instruction buttons may include a button forgiving an instruction regarding the movement direction of the stack selected by the operator and a button forgiving an instruction regarding the arrangement of the stacks selected by the operator.

In addition, the MRI apparatus 100 may further include the input device 174 to receive the instruction from the operator, and the adjustment section 224 may be configured to perform an adjustment by updating at least one of the display position of the stack 420 and the number of stacks 420 according to an instruction from the operator with respect to the stack 420 through the input device 174.

Thus, according to the present embodiment, the stack 420 is displayed at the desired imaging position among the imaging positions detected by the automatic positioning section 221 without interfering with the visibility of the status of tissue and the structure of a positioning image at the back. Therefore, it is easy to understand the imaging position on the positioning image, and it is easy to determine the validity by relationship with a positioning image at the back.

In addition, when the number of designated stacks set by the imaging parameter is different from the number of output imaging positions set as the output pattern, the place of mismatch is displayed with the display form changed. Accordingly, the operator can easily check the position, which is actually used in the main imaging, among the imaging positions detected by the automatic positioning section 221. Since the operator can perform an adjustment while viewing such a display, adjustment work becomes easy. Therefore, according to the present embodiment, even if a part with a plurality of examination sections is an examination target, the advantage of the automatic positioning function, which is a positioning time reduction, is still effective.

In addition, according to the present embodiment, the setting of the output pattern, which includes examination sections and the number of examination sections, according to an examination part is performed using a dedicated interface. Therefore, even if a part having a plurality of examination sections is an examination target, the operator can set the output pattern easily.

In addition, according to the present embodiment, when the number of designated stacks that is designated by the imaging parameter is different from the number of output imaging positions set as the output pattern, adjustment, such as the adjustment of the output imaging position to which the stack 420 is assigned or an increase or decrease in the number of output imaging positions, is performed using a dedicated interface. Thus, since the present embodiment includes simple adjustment means with good operability, adjustment work can also be easily intuitively performed. As a result, not only can the adjustment work become easy, but also high-accuracy adjustment can be performed regardless of the operator.

Therefore, according to the present embodiment, even in the imaging of a part having a plurality of positions that can be set as imaging positions, automatic output of the positioning position suitable for the purpose of examination becomes possible. If the adjustment of the output position is not required, main imaging can be performed as is. On the other hand, even if the adjustment of the output position is required, the adjustment can be easily performed intuitively. Therefore, the number of operations is reduced as the entire examination, and the load on the operator is reduced.

In addition, although the examination section is set in step S1002 according to an examination part and is stored with a name in step S1003 for each examination in the embodiment described above, the present invention is not limited thereto. Each output pattern may be created in advance according to an examination part for each examination section and the number of examination sections, which can be selected, and be registered in the data storage unit 240 with the name. That is, the MRI apparatus 100 may further include a data storage unit that stores selectable examination sections as output patterns in advance for each examination part, and the output pattern setting section 222 may receive the setting of the output examination section by receiving a selection from the output patterns stored in the data storage unit.

In this case, the processing of above-described steps S1002 and S1003 does not need to be performed. That is, in step S1001, when an examination part is set, the imaging condition setting unit 210 proceeds to step S1004 and displays the protocol setting screen 500 on the display device 173. In this case, the protocol setting screen 500 is configured such that the selection of the output pattern is also received when receiving a setting for performing automatic positioning in the parameter setting region 520. Then, the imaging condition setting unit 210 displays the output pattern name of the output pattern created in advance by menu display or the like, receives the selection of the operator, and creates an examination protocol according to the received selection and stores it.

In addition, when creating a plurality of output patterns in advance and storing the output patterns in the data storage unit 240, output patterns to be used may be configured so as to be changeable at an arbitrary timing. For example, output patterns to be used may be configured so as to be changeable on the examination screen 600 displayed in above-described step S1005. Also in this case, the output pattern name may be configured so as to be selectable by menu display or the like.

Through such a configuration, for example, in the above-described example, the vertebral body selected on the protocol setting screen 500 can be changed to the intervertebral disc on the examination screen 600. In this case, the stack 420 is displayed in the changed output pattern after automatic positioning processing.

In addition, when creating a plurality of output patterns in advance and storing the output patterns in the data storage unit 240, the output pattern may be configured so as to be changeable after the stack 420 is displayed in step S1009. In this case, whenever the output pattern is changed, the process returns to step S1008 in which the automatic positioning section 221 performs automatic positioning and the detection result display section 223 displays the stack 420 according to the output pattern. In addition, when all imaging positions of a part to be examined can be detected by the automatic positioning section 221, it is preferable to return to step S1009 without performing the automatic positioning again whenever the output pattern is changed, so that the imaging position output from the detection result display section 223 is changed to an imaging position according to the output pattern.

In addition, although the case where the output pattern of the cross-section in one axial direction is set and the imaging position in the direction is set has been described as an example in the above embodiment, the present invention is not limited thereto. For each of sagittal, coronal, and axial cross-sections, when there are options of a plurality of examination sections, the output pattern setting section 222 sets the output pattern and stores the output pattern with a name. In addition, the examination section may be selected on the protocol setting screen 500 or the examination screen 600.

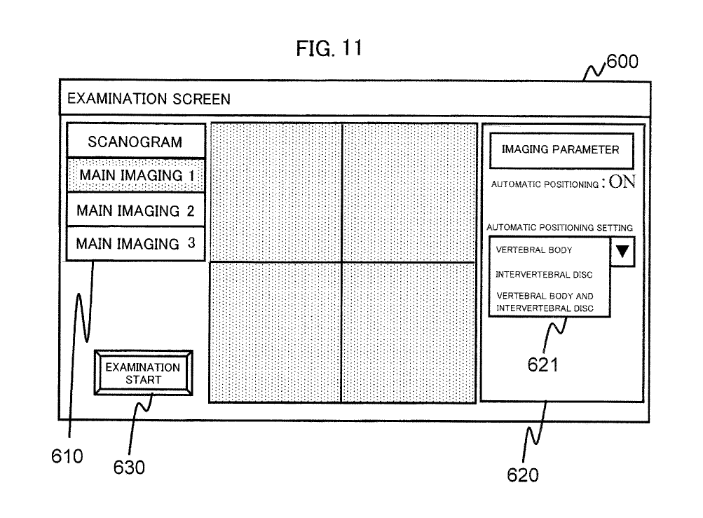

In addition, depending on a part, there may be a small number of options in selecting the examination section. In this case, it is not necessary to prepare the output pattern setting screen 300. In addition, for example, a menu to select an examination section may be disposed on the examination screen 600 or the protocol setting screen 500, so that the examination section is selected there. FIG. 11 shows a case where the examination screen 600 includes a menu 621 to select an examination section. In this case, the operator selects an examination section when selecting each imaging parameter. The detection result display section 223 displays the stack 420 according to the selection.

In addition, in this case, the number of detections cannot be selected. Therefore, in the case of an examination section having a plurality of imaging positions, the number of designated stacks set by the imaging parameter may be set as the number of detections. In addition, the stack 420 may be displayed at all imaging positions, and the selection of the operator may be received.

In addition, the timing of the output pattern setting is not limited to the above. For example, the timing of the output pattern setting may be after the acquisition of a scanogram image or may be after the acquisition of an image by main imaging. That is, the next examination section is determined while viewing the obtained image.

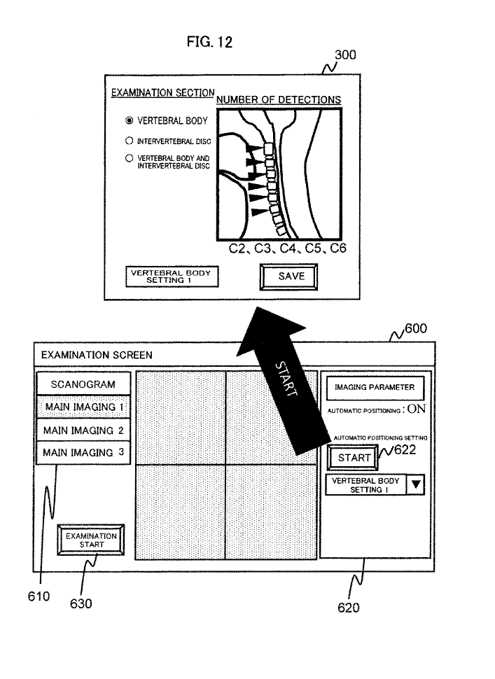

FIG. 12 illustrates the examination screen 600 in this case. Here, a start button 622 for calling the output pattern setting screen 300 is disposed in an imaging parameter setting portion of the examination screen 600 that displays an image obtained after each imaging. The imaging condition setting unit 210 displays the output pattern setting screen 300 in response to the pressing of the start button 622.

In the above embodiment, a screen example displayed on the display device 173, such as the output pattern setting screen 300, has been described with the case where the examination part is a spine region as an example. An example of another examination part will be described below.

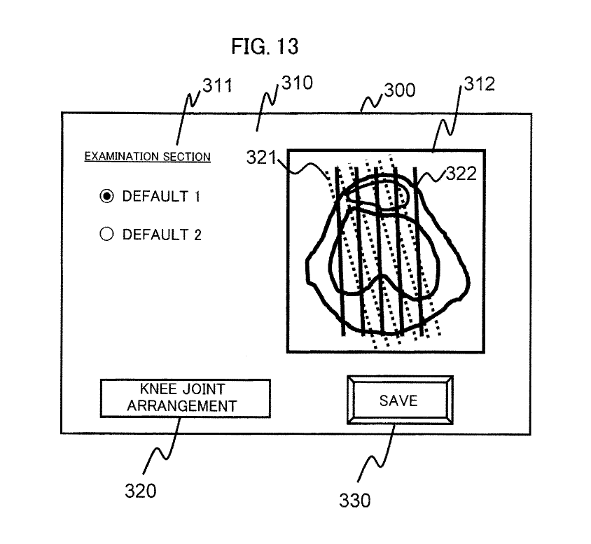

FIG. 13 shows an example of the output pattern setting screen 300 when the examination part is a knee joint. In the knee joint, there are examination sections, such as a meniscus and a cruciate ligament. Here, a case where an output imaging position desired as an automatic positioning output is selected according to the purpose of examination from the basic positioning positions set in advance instead of designating the output imaging position using an examination section name will be described as an example. Each of the basic positioning positions is set in advance as a default examination section according to the purpose of examination for each apparatus, and is registered in the data storage unit 240. In addition, the output pattern setting section 222 sets the output pattern of each object on the basis of the default examination section.

A name given to each default examination section is displayed in the examination section setting region 311. Here, default 1 and default 2 are set. When the name is selected, the output pattern setting section 222 extracts a positioning position (default 1) 321, which is registered in the data storage unit 240 so as to match the name, and displays the positioning position 321 on the standard image of the number-of-detections setting region 312. The operator changes the displayed positioning position 321 by an operation using the input device 174, and determines a positioning position 322. When the name is input to the output pattern name setting region 320 and the pressing of the save button 330 is received, the output pattern setting section 222 registers the positioning position 322, which is displayed on the standard image at that point in time, as an output pattern in the data storage unit 240 so that the positioning position 322 matches the output pattern name.

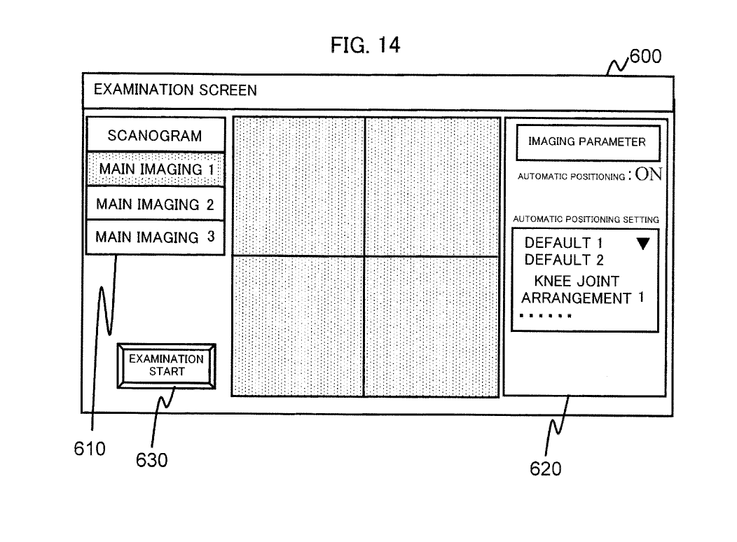

In this case, when automatic positioning is set on the protocol setting screen 500 and the examination screen 600, not only the default examination section but also the output pattern created by the operator using the output pattern setting screen 300 can be selected. FIG. 14 shows an example of the examination screen 600 configured such that the above selection is possible.

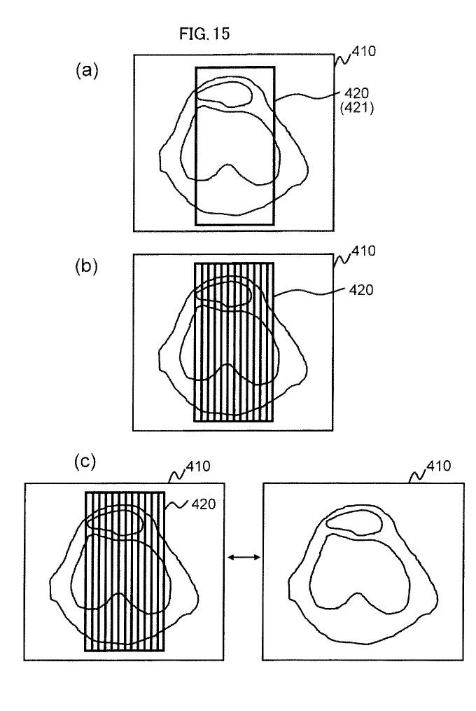

In addition, FIG. 15 shows a specific example of the display of the stack 420 when the examination part is a knee joint. FIG. 15(a) is an example of the stack 420 when only the imaging range is displayed in the rectangle 421 at the output imaging position on the positioning image 410 without displaying a plurality of slices forming an examination section. FIG. 15(b) is an example in which the stack 420 is displayed at the output imaging position on the positioning image 410 so as to blink. FIG. 15(c) is an example in which the display/non-display of the stack 420 is changed according to the instruction from the operator.

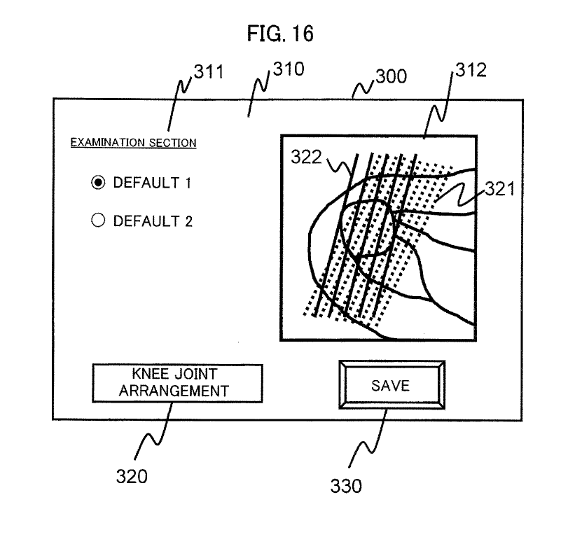

In addition, FIG. 16 shows an example of the output pattern setting screen 300 when the examination part is a shoulder joint. Also when the examination part is the shoulder joint, a case where a default examination section is created in advance for each apparatus and is registered in the data storage unit 240 with a name is illustrated as in the case of the knee joint. The other processes are the same as those in the case of the knee joint.

That is, a name given to each default examination section is displayed in the examination section setting region 311. Here, default 1 and default 2 are set. When the name is selected, the output pattern setting section 222 extracts the positioning position (default 1) 321, which is registered in the data storage unit 240 so as to match the name, and displays the positioning position 321 on the standard image of the number-of-detections setting region 312. The operator changes the displayed positioning position 321 by an operation using the input device 174, and determines the positioning position 322. When the name is input to the output pattern name setting region 320 and the pressing of the save button 330 is received, the output pattern setting section 222 registers the positioning position 322, which is displayed on the standard image at that point in time, as an output pattern in the data storage unit 240 so as to match the output pattern name.

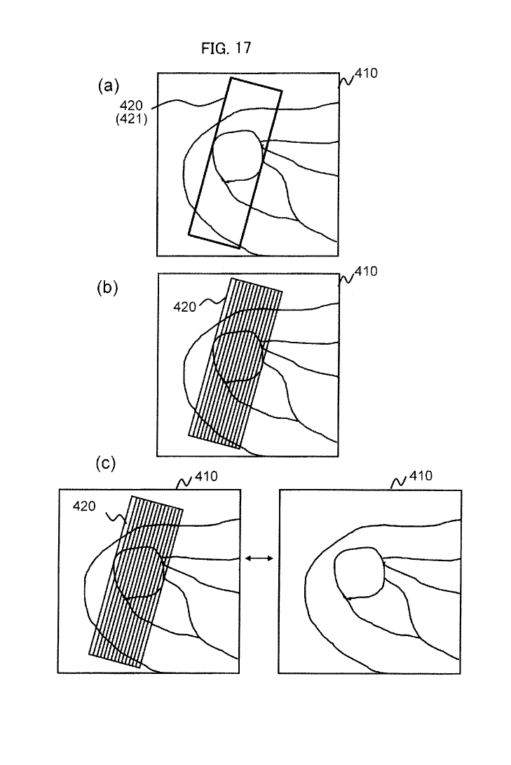

FIG. 17 shows a specific example of the display of the stack 420 when the examination part is a shoulder joint. FIG. 17(a) is an example of the stack 420 when only the imaging range is displayed in the rectangle 421 at the output imaging position on the positioning image 410 without displaying a plurality of slices forming an examination section. FIG. 17(b) is an example in which the stack 420 is displayed at the output imaging position on the positioning image 410 so as to blink. FIG. 17(c) is an example in which the display/non-display of the stack 420 is changed according to the instruction from the operator.

### Second Embodiment

Next, a second embodiment to which the present invention is applied will be described. In the present embodiment, the operator can select an output imaging position, which is displayed as a stack, after automatic positioning.

An MRI apparatus of the present embodiment has basically the same configuration as the MRI apparatus 100 of the first embodiment. In the present embodiment, however, the selection of an output imaging position, which is displayed as a stack, from the imaging positions of the obtained examination sections is received after automatic positioning according to the set output pattern as described above. For this reason, the configuration of the imaging position setting unit 220 of the control processing system 170 is different. Hereinafter, the present embodiment will be described focusing on the different configuration from the first embodiment.

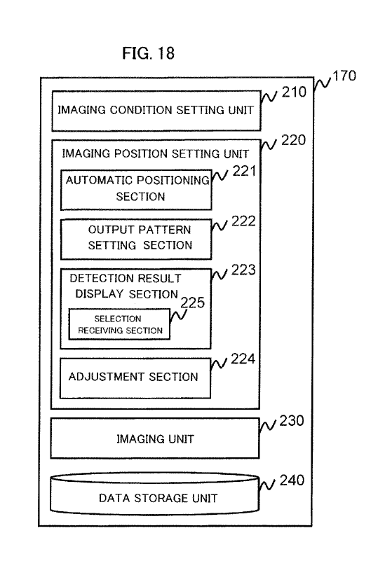

FIG. 18 is a functional block diagram of the imaging position setting unit 220 of the present embodiment. As shown in this diagram, the present embodiment includes the automatic positioning section 221, the output pattern setting section 222, the detection result display section 223, and the adjustment section 224 as in the first embodiment. In addition, the detection result display section 223 includes a selection receiving section 225 that receives the selection of an output imaging position, at which the stack 420 is displayed, from the imaging positions of the set examination sections. In addition, each function of the automatic positioning section 221, the output pattern setting section 222, and the adjustment section 224 is the same as that in the first embodiment. Hereinafter, the detection result display section 223 of the present embodiment will be described.

When the automatic positioning section 221 performs positioning processing, the detection result display section 223 of the present embodiment displays the imaging position of the set examination section on the positioning image as in the first embodiment. The display performed at this time is assumed to be a simple display instead of the stack 420. The simple display is displayed in a form in which there is no interference with the visibility of the positioning image and the operator can check the position and inclination of the examination section.

Also in the present embodiment, as in the first embodiment, the detection result display section 223 generates a detection result display screen and displays the detection result display screen on the display device 173, for example. In addition, the detection result display section 223 of the present embodiment performs simple display at the imaging position of the set examination section on the positioning image 410 of the detection result display screen, and receives the selection of the imaging position to display the stack 420. As will be described later, the selection of the imaging position to display the stack 420 is received by the selection receiving section 225.

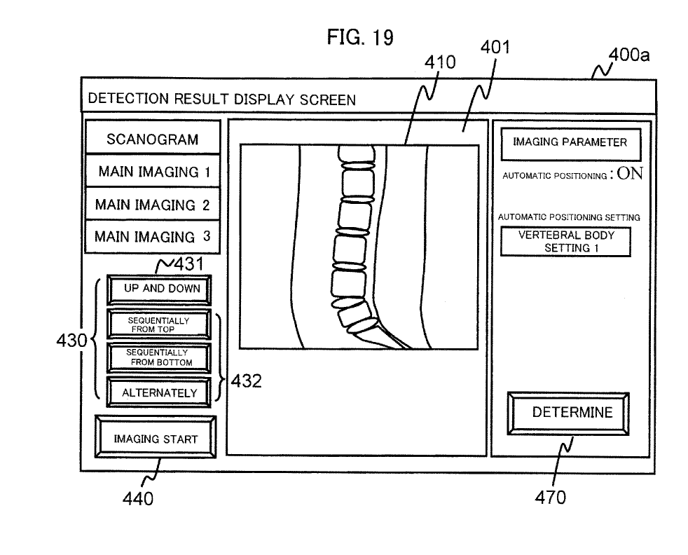

FIG. 19 shows an example of a detection result display screen 400a displayed by the detection result display section 223 of the present embodiment. The detection result display screen 400a of the present embodiment is also generated by the imaging position setting unit 220 or the detection result display section 223 using the data stored in the data storage unit 240 and displayed on the display device 173 as in the first embodiment. As shown in FIG. 19, the detection result display screen 400a includes a display region 401 where a positioning image 410 is displayed, an adjustment instruction region 430 where various buttons used for the adjustment of the output imaging position are displayed, and an imaging start button 440 for receiving the intention to determine the output imaging position and the instruction to start imaging. Each of these functions is the same as the function of the same name of the detection result display screen 400 of the first embodiment. In addition, the detection result display screen 400a of the present embodiment includes a determine button 470 for receiving the intention to determine the selection of the imaging position where the stack 420 is displayed.

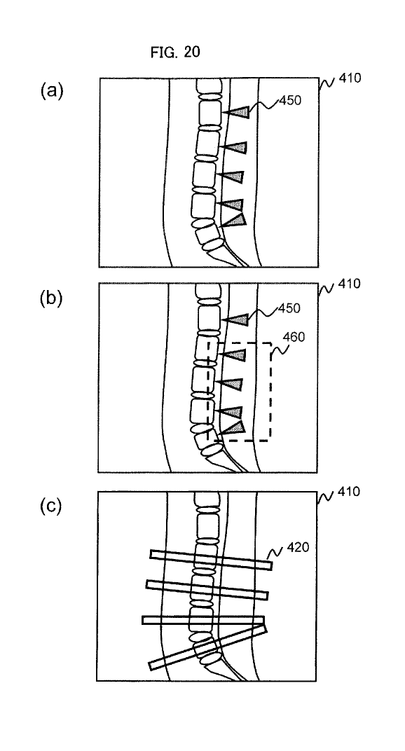

FIG. 20 is a diagram for explaining the processing of the detection result display section 223 and the selection receiving section 225 of the present embodiment. Here, a case where the spine region is selected as an examination part and the vertebral body is selected as an examination section will be described as an example. The cross-section of the spine is displayed as the positioning image 410. FIG. 20(a) is a diagram showing a display example of the detection result display section 223 of the present embodiment. FIG. 20(b) is a diagram for explaining a state where the selection receiving section 225 receives the selection of the operator. FIG. 20(c) is a diagram for explaining the stack 420 displayed on the positioning image 910.

A simple display 950 is displayed at the imaging position of the set examination section on the positioning image 910 of the display region 901. FIG. 20 (a) shows a specific example of the display. FIG. 20(a) is an example in which an arrow head is used as the simple display 950. The tip position of the arrow head is a detected imaging position, and the inclination of the arrow head indicates the inclination of the detected examination section. The display form of the simple display 450 is not limited thereto.

The selection receiving section 225 of the present embodiment receives the selection of the output imaging position by the operator on the positioning image 410 in which the simple display 450 is displayed. The selection is received, for example, by surrounding the desired simple display 950 with a rectangular region selection frame 960 using the input device 174 as shown in FIG. 20(b). Release of the selection is received, for example, by placing and clicking the mouse button in the displayed region selection frame 460. Methods of selecting and releasing the simple display 450 are not limited thereto.

Upon completion of selection, the operator presses the determine button 470 to notify the selection receiving section 225 that the simple display 450 (imaging position) to be selected has been determined. In response to the pressing of the determine button 470, the selection receiving section 225 determines that the simple display 450 (imaging position) surrounded by the rectangular region selection frame 460 at that point in time has been selected.

When the notification of the selected simple display 450 (imaging position) is received from the selection receiving section 225, the detection result display section 223 displays the stack 420 at the position of the selected simple display 450 (imaging position) on the positioning image 410, as shown in FIG. 20(c).

The flow of the examination by each function of the control processing system 170 of the present embodiment is basically the same as the process flow of the first embodiment shown in FIG. 8. However, new processing is inserted between the automatic positioning in step S1008 and the stack display processing in step S1009. In the first embodiment, when the automatic positioning section 221 ends the automatic positioning processing and the imaging position is detected, the detection result display section 223 sets the imaging position corresponding to the examination section as an output imaging position and displays the stack 420 at the corresponding position on the positioning image 410. In this case, as shown in FIG. 8(b), either the surplus stack 422 or the insufficiency stack 423 is displayed together as necessary. On the other hand, in the present embodiment, the imaging position selected from the detected imaging positions by the operator is set as an output imaging position, and the stack 420 is displayed there.

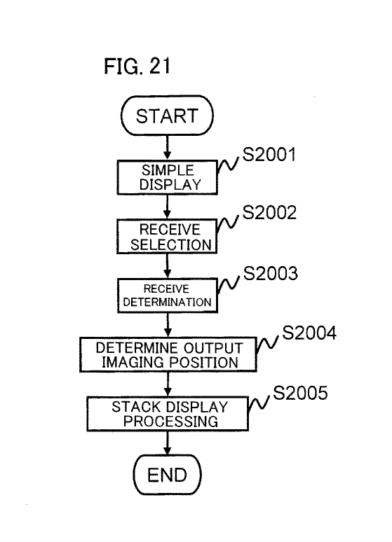

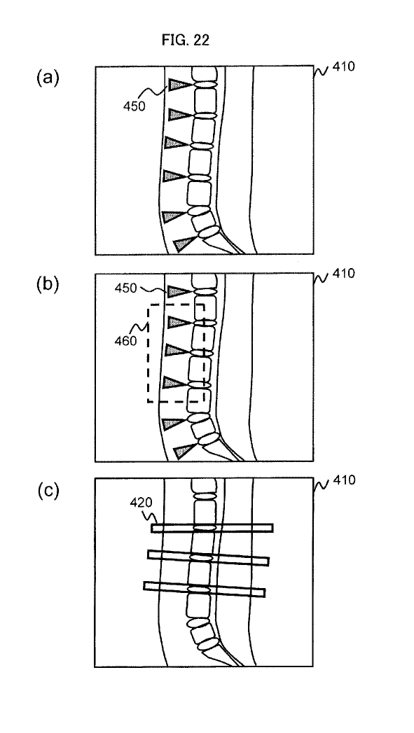

FIG. 21 shows the flow of the process up to the stack display processing in step S1009 after the automatic positioning processing in step S1008 of the present embodiment. In addition, display on the positioning image 410 in each processing will be described with reference to FIG. 22. Here, a case where the examination part is a spine region and the examination section is an intervertebral disc is illustrated as an example.

In the present embodiment, when the automatic positioning section 221 detects an imaging position, the detection result display section 223 performs the simple display 450 at the imaging position of the set examination section on the positioning image 410 as shown in FIG. 22(a) (step S2001).

Then, the selection receiving section 225 receives the selection of the simple display 450 from the operator (step S2002). As shown in FIG. 22(b), the selection is performed by surrounding the simple display 450 at a position, which needs to be selected, with the rectangular region selection frame 460. In response to the pressing of the determine button 470 (step S2003), the selection receiving section 225 determines the simple display 450 (imaging position) selected at that point to be a selected imaging position (step S2004), and sends the notification to the detection result display section 223. The detection result display section 223 sets the selected imaging position as an output imaging position, and performs stack display processing for displaying the stack 420 at a position corresponding to the output imaging position on the positioning image 410 as shown in FIG. 22(c) (step S2005).

In addition, the stack display processing using the determined output imaging position of the present embodiment in step S2005 is the same as the stack display processing of the first embodiment shown in FIG. 8(b). In addition, processing after the stack display S1009 is basically the same as that in the first embodiment. That is, as in the first embodiment, the adjustment section 224 receives an adjustment for the output imaging position where the stack 420 is displayed. In addition, when an instruction to start imaging is received through the imaging start button 440, the imaging position setting unit 220 sets the output imaging position, at which the stack 420 is displayed at that point in time, as an imaging position in main imaging. All pieces of data under these processes are stored in the data storage unit 240 built in the storage device 172.

As described above, the MRI apparatus 100 of the present embodiment is the MRI apparatus 100 including the control processing system 170, which performs calculation and control of the operation of the entire apparatus, and the display device 173. The control processing system 170 includes the imaging condition setting unit 210 that receives a setting for performing an examination, the imaging position setting unit 220 that sets an imaging position, and the imaging unit 230 that images the imaging position set by the imaging position setting unit 220. The imaging position setting unit 220 includes the automatic positioning section 221 that detects the positions of all examination sections of the examination part, which is received by the imaging condition setting unit 220, on the scanogram image acquired in advance and the detection result display section 223 that displays the scanogram image on the display device 173 and that sets one or more positions determined in advance, among the positions detected by the automatic positioning section 221, as the imaging positions and displays the stack 420 at the imaging positions on the scanogram image while ensuring visibility. In this case, the detection result display section 223 may include the selection receiving section 225 that receives the selection of a position set as the imaging position.

In addition, the MRI apparatus 100 may further include the input device 174 to receive the input from the operator. The detection result display section 223 may perform the simple display 450 at a position, which is detected by the automatic positioning section 221, on the scanogram image. The selection receiving section 225 may receive the selection of the position by receiving the selection of the simple display 450 through the input device 174. The simple display 450 may be a display in which there is no interference with the visibility of the scanogram image and the position and the inclination of the detected examination section can be checked.

In addition, the imaging position setting unit 220 may further include the output pattern setting section 222 that sets the examination section, which is set as the imaging position, as an output pattern. The detection result display section 223 may perform the simple display 450 at the position of the examination section set as the output pattern, among the positions detected by the automatic positioning section 221, on the scanogram image. The selection receiving section 225 may receive the selection of the position by receiving the selection of the simple display 450 through the input device 174. The simple display 450 may be a display in which there is no interference with the visibility of the scanogram image and the position and the inclination of the detected examination section can be checked.

Thus, the MRI apparatus of the present embodiment has basically the same configuration as in the first embodiment. Therefore, the same effects as in the first embodiment are obtained. In addition, in the MRI apparatus of the present embodiment, the operator can select a desired imaging position from the imaging positions detected by the automatic positioning section 221. Therefore, according to the present embodiment, it is possible to provide an MRI apparatus, which is more convenient for the operator and has high operability, in determining the imaging position.

In addition, although the case where there is one kind (vertebral body or intervertebral disc in the case of a spine region) of examination section has been described as an example in the above embodiment, a plurality of examination sections may also be set.

In addition, although the case where the examination section or the examination section and the number of examinations are set in advance by the output pattern setting section 222 has been described as an example in the above embodiment, setting the examination section or the examination section and the number of examinations in advance may be omitted. In this case, the detection result display section 223 performs the simple display 450 at the imaging positions of all of the detected examination sections.

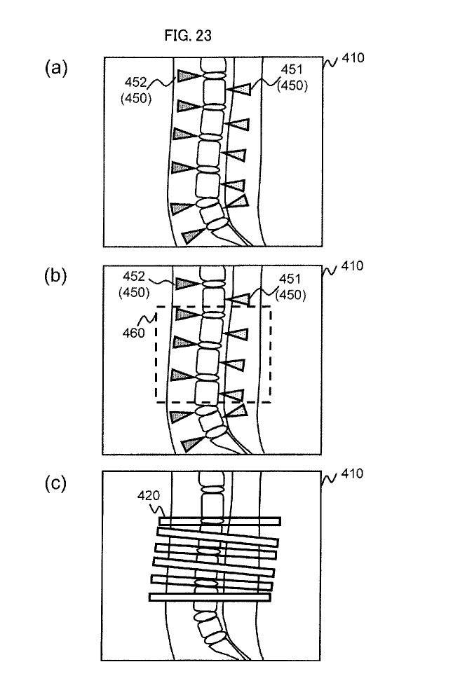

Stack display processing of the detection result display section 223 in this case will be described with reference to FIGS. 23(a) to 23(c). Here, a case where a spine region is selected as an examination part is illustrated as an example.

When the examination part is a spine region, the vertebral body and an intervertebral disc are included in the examination sections. Accordingly, the automatic positioning section 221 detects the imaging positions of all examination sections, that is, all imaging positions of the vertebral body and the intervertebral disc. First, as shown in FIG. 23(a), the detection result display section 223 performs the simple display 450 at the imaging positions of both the vertebral body and the intervertebral disc. In addition, in this case, as shown in this diagram, the simple display 450 may be performed in a manner different for each examination section. For example, the different manner is to change the display position or to change the display form. In this diagram, an example is shown in which a simple display 452 at an output imaging position corresponding to the intervertebral disc is displayed on the left side of the spine and a simple display 451 at an output imaging position corresponding to the vertebral body is displayed on the right side of the spine and the simple display 451 and the simple display 452 are displayed in different colors.

In addition, even if the presetting of the examination section or the like is not performed, the selection of the desired imaging position is performed using a method of surrounding the desired simple display 450 with the region selection frame 460, such as a rectangle, in the same manner as described above as shown in FIG. 23(b). In addition, as shown in FIG. 23(c), the detection result display section 223 displays the stack 420 at the selected position of the simple display 450 regardless of the type of the examination section.

In addition, this is the same for a case where a plurality of examination sections are set in the output pattern setting processing. That is, when the examination part is a spine region, if the vertebral body and the intervertebral disc are set as examination sections, the simple display 450 may be displayed in a manner different for each examination section as shown in FIG. 23(a) when performing the simple display 450 at the imaging position of the set examination section.

Thus, when presetting processing for designating the examination section or the like is not performed, the detection result display section 223 performs the simple display 450 in a manner in which the position and the inclination of the examination section are specified at the imaging position and the operator can check the structure of the examination part and the state of tissue on the positioning image 410, and the selection receiving section 225 receives the selection of the output imaging position through the simple display. Through such a configuration, it is possible to simplify the output pattern setting processing. Therefore, it is possible to provide an MRI apparatus with higher operability.

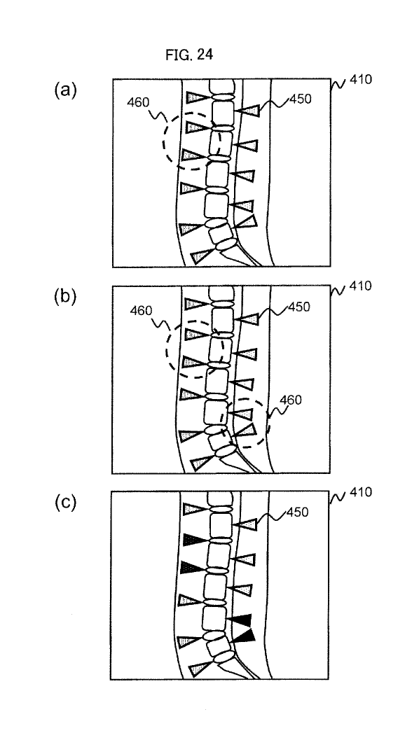

In addition, in the present embodiment, the case where a region is selected by the rectangular region selection frame 460 when selecting a desired position from the output imaging positions has been described as an example. However, the present invention is not limited thereto. The simple display 450 corresponding to the desired position may also be selected by the region selection frame 460 having other shapes, for example, a circular shape shown in FIG. 24(a), an elliptical shape, and a polygonal shape. In addition, as shown in FIG. 24(b), a plurality of regions may be configured so as to be selectable. In this case, the stack 420 is displayed at the positions of all simple displays 450 selected when the determine button 470 is pressed. In addition, the simple display 450 itself at the desired position may be selected by an operation of clicking the mouse pointer or the like.

In all of the selection methods, the selected simple display 450 may be displayed in a manner different from the simple display 450 that is not selected. Examples of the different manner include changing the display color as shown in FIG. 24(c). In addition, when an arrow head is used as the simple display 450, for example, the thickness and shape of the line of the outer frame may be changed.

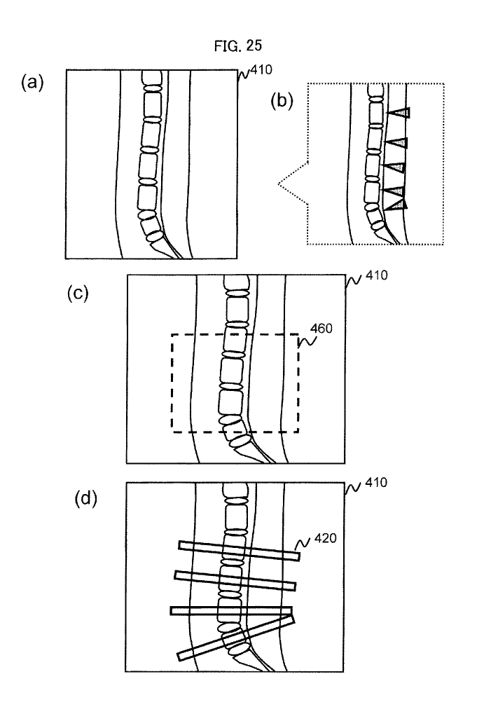

In addition, although the simple display 450 is performed at the predetermined imaging position detected by the automatic positioning section 221 in the present embodiment, the simple display 450 may not be performed. FIG. 25 shows the flow of the stack display processing in this case. Here, only the positioning image 410 will be described in an example when the spine region is selected as an examination part and the vertebral body is selected as an examination section.

In this case, as shown in FIG. 25(a), the detection result display section 223 does not perform the simple display 450 in the above-described step S2001. Here, the position information of the imaging position of the set examination section is internally stored, as shown in FIG. 24(b).

Then, as shown in FIG. 24(c), the selection receiving section 225 receives the selection of a region on the positioning image 410 without the simple display 450.

Then, the selection receiving section 225 notifies the detection result display section 223 of the selected region in response to the pressing of the determine button 470. The detection result display section 223 determines the imaging position of the set examination section within the selected region to be the selected imaging position, and sets it as the output imaging position. The detection result display section 223 displays the stack 420 at the output imaging position on the positioning image 410, as shown in FIG. 24(d).

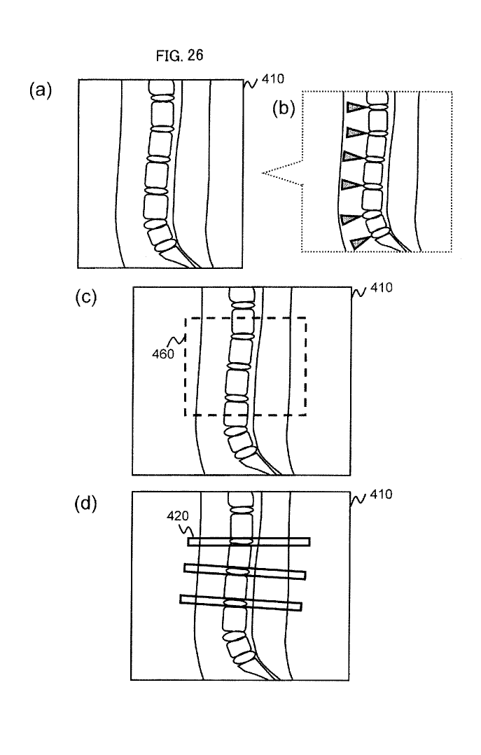

In addition, this is the same for a case where the selected examination section is an intervertebral disc. FIGS. 26(a) to 26(d) show a state of the positioning image 410 at the time of stack display processing in this case.

That is, as shown in FIG. 26(c), the detection result display section 223 and the selection receiving section 225 receive the selection of a region on the positioning image 410 having no simple display 450 as in FIG. 26(a). After determining the region selection, the stack 420 is displayed at the imaging position of the intervertebral disc within the selected region, as shown in FIG. 26(d). In addition, the position information of the imaging position of the detected intervertebral disc is internally stored, as shown in FIG. 26(b).

In addition, this is the same for a case where there is no presetting of the examination section or the like or a case where a plurality of examination sections are selected at the time of output pattern setting. Here, a case where the spine region is an examination part will be described as an example. When the examination part is a spine region, there are two kinds of examination sections of the vertebral body and the intervertebral disc. Accordingly, a case where no examination section is set and a case where the vertebral body and the intervertebral disc are selected as examination sections are the same. FIGS. 26(a) to 26(d) show a state of the positioning image 410 at the time of stack display processing in this case.

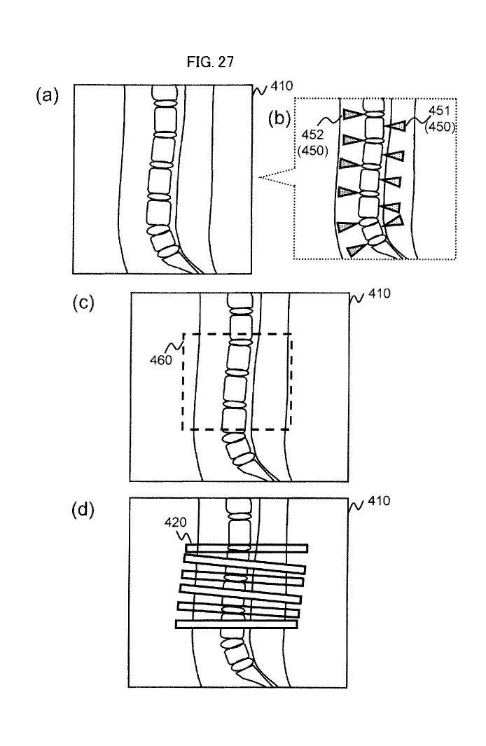

As shown in FIG. 27(c), the detection result display section 223 and the selection receiving section 225 receive the selection of a region on a positioning image having no simple display 450 as in FIG. 27(a). After determining the region selection, the stack 420 is displayed at all imaging positions within the selected region, as shown in FIG. 27(d). In addition, the position information of all the detected imaging positions is internally stored, as shown in FIG. 27(b).

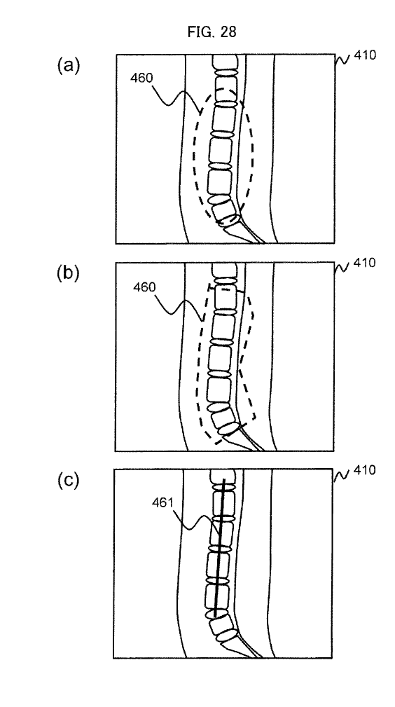

In addition, also when there is no simple display, the region selection method is not limited to the rectangular region selection frame 460. For example, as shown in FIGS. 28 (a) and 28(b), it is also possible to use the region selection frame 460 of other shapes. FIG. 28(a) shows an example in which the operator designates a selection region with an elliptical frame. In addition, FIG. 28(b) shows an example in which the operator designates a selection region with a polygon.

In addition, for example, as shown in FIG. 28(c), a region to be selected may be designated using a method, such as pulling a line 461 that designates a range to be selected. The detection result display section 223 sets an output imaging position, of which the coordinate value in the body axis direction is within a range of the positions (coordinate values) of both ends of the line 461 in the body axis direction, as a selected output imaging position, and displays the stack 420.

Thus, the MRI apparatus of this modification includes the input device 179 that receives the input from the operator, and the selection receiving section 225 receives the selection of a region on the scanogram image through the input device 174 and sets a position within the selected region, among the positions detected by the automatic positioning section 221, as the selected position. In addition, the imaging position setting unit 220 may further include the output pattern setting section 222 that sets the examination section, which is set as the imaging position, as an output pattern. The selection receiving section 225 may receive the selection of a region on the scanogram image through the input device 174 and set a position within the selected region, which is the position of the examination section set as the output pattern among the positions detected by the automatic positioning section 221, as the selected position. For this reason, since there is no simple display 450, the operator can select an imaging region in a state where there is no interference with the visibility of the positioning image 410. Therefore, according to this modification, it is possible to acquire the higher operability.

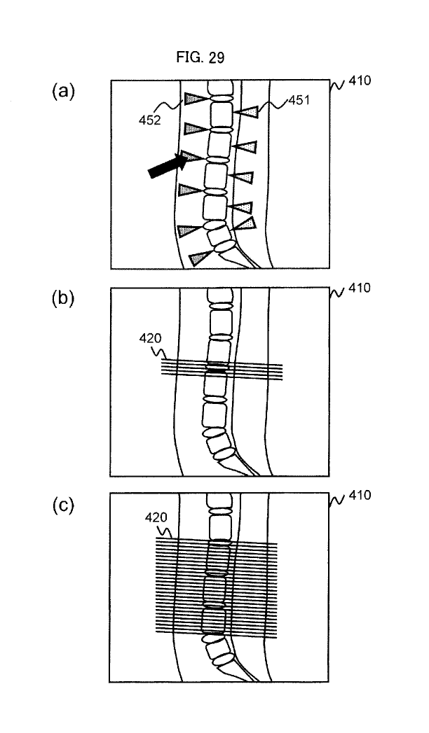

In addition, when performing multi-slice imaging at the selected imaging position, the number of slices can be increased or decreased. That is, when each examination section is configured to include one or more slices, the adjustment section 224 receives the change of the number of slices of the examination section according to the instruction from the operator with respect to the stack 420. This processing is performed by the adjustment section 224. Hereinafter, this method will be described with reference to FIG. 29. Here, as described above, a case where the examination part is a spine region and the vertebral body and the intervertebral disc are selected as examination sections is illustrated. The same applies to a case where one kind of examination section is selected and a case where the selection of the examination section is not performed.

As shown in FIG. 29(a), when the simple display 450 (simple display 451 showing the vertebral body surface, simple display 452 showing the intervertebral disc surface) is performed by the detection result display section 223, the selection receiving section 225 receives a selection range from the operator. Although a case where one simple display 450 is selected by selecting the simple display 450 by the arrow head, which is displayed at a desired position, using a mouse or the like is illustrated herein, it is also possible to select a region as described in the above example of the present embodiment. In addition, the number of selected simple displays 450 is not limited to 1.

When the selection is received, the detection result display section 223 displays the stack 420 at the imaging position within the received selection range, as shown in FIG. 29(b). The stack 420 to be displayed is displayed in parallel to the detected examination section at the selected imaging position. In addition, in this modification, since it is assumed that the multi-slice imaging is performed, the stack 420 is displayed in a manner that it is possible to see that there is a plurality of slices. For example, it is preferable to display lines of the number of slices, which is set by the imaging parameter in advance, at slice intervals set by the imaging parameter.

In addition to the fine adjustment of the imaging position described in the first embodiment, the adjustment section 224 receives an instruction to increase or decrease the number of slices. For example, the instruction is given using a method, such as expanding the stack 420 until the required number of slices in a direction, in which the number of slices is to be increased, by drag operation. In this case, the angle of the stack 420 is fixed.

Here, the adjustment section 224 receives such an instruction from the operator, and calculates the number of slices from the slice interval set by the imaging parameter and the size of the stack 420 in the slice direction after enlargement. In addition, each imaging slice position is calculated from the information of the detection position (imaging position), the number of slices, and the slice interval. In this case, the number of slices may be displayed as a numerical value.

In addition, when the operator selects a plurality of simple displays 450 (imaging positions), an increase or decrease in the number of slices is performed in a range not overlapping the adjacent stack 420.

Thus, according to this modification, the adjustment section 224 further receives an instruction to change the number of slices of the selected output imaging position and further adjusts the number of slices according to the received instruction, and the detection result display section 223 displays the stack 420 at the output imaging position after the adjustment.

Through such a configuration, the operator can perform multi-slice imaging in accordance with the detection angle of the imaging position by selecting the imaging position of a desired angle. Therefore, it is possible to acquire the higher operability.

In addition, in order to increase or decrease the number of slices, parameters may be directly changed as well as the mouse operation. The adjustment section 224 receives parameter changes, and displays the stack 420 so as to have the number of slices and the slice interval specified by the changed parameters.

In addition, the adjustment of the position of each slice displayed as the stack 420 may be received. In this case, since the adjustment of the slice interval can also be received, the operator can adjust the slice interval easily. The adjustment of the slice interval may also be received by parameter changes.

In addition, although the control processing system 170 of the MRI apparatus 100 has the function of the imaging position setting unit 220 in the above explanation of each embodiment, the present invention is not limited thereto. For example, the imaging position setting unit 220 may also be built on an information processing apparatus that is provided separately from the MRI apparatus 100 and that can transmit and receive data to and from the MRI apparatus 100.

In addition, although the MRI apparatus has been described as an example in each of the above embodiments, the imaging position setting method of each embodiment can be applied to a typical medical imaging apparatus that sets the position of an imaging slice to perform imaging.

### REFERENCE SIGNS LIST

100: MRI apparatus
101: object
120: static magnetic field generation system
130: gradient magnetic field generation system
131: gradient magnetic field coil
132: gradient magnetic field power source
140: sequencer
150: signal transmission system
151: transmission coil
152: high frequency oscillator
153: modulator
154: high frequency amplifier
160: signal receiving system
161: receiving coil
162: signal amplifier
163: quadrature phase detector
164: A/D converter
170: control processing system
171: CPU
172: storage device
173: display device
174: input device
210: imaging condition setting unit
220: imaging position setting unit
221: automatic positioning section
222: output pattern setting section
223: detection result display section
224: adjustment section
225: selection receiving section
230: imaging unit
240: data storage unit
300: output pattern setting screen
310: output pattern setting region
311: examination section setting region
312: number-of-detections setting region
320: output pattern name setting region
321: default positioning position
322: positioning position
330: save button
400: detection result display screen
400a: detection result display screen
401: display region
410: positioning image
420: stack
421: outer frame
422: surplus stack
423: insufficiency stack
430: adjustment instruction region
431: direction instruction button
432: arrangement instruction button
440: imaging start button
450: simple display
451: simple display
452: simple display
460: region selection frame
461: line
470: determine button
500: protocol setting screen
510: imaging type setting region
520: parameter setting region
530: save button
600: examination screen
610: imaging type display region
620: parameter display region
621: menu
622: start button
630: examination start button

1. A magnetic resonance imaging apparatus, comprising:
a control processing system that performs calculation and control of an operation of the entire apparatus; and
a display device,
wherein the control processing system includes an imaging condition setting unit that receives a setting for performing an examination, an imaging position setting unit that sets an imaging position, and an imaging unit that images the imaging position set by the imaging position setting unit, and
the imaging position setting unit includes an automatic positioning section that detects positions of all examination sections of an examination part, which is received by the imaging condition setting unit, on a scanogram image acquired in advance and a detection result display section that displays the scanogram image on the display device and that sets one or more positions determined in advance, among the positions detected by the automatic positioning section, as the imaging positions and displays a stack at the imaging positions on the scanogram image.

2. The magnetic resonance imaging apparatus according to claim 1,
wherein the imaging position setting unit further includes an output pattern setting section that sets the examination sections, which are set as the imaging positions, as output patterns, and
the one or more positions determined in advance are positions of the examination sections, which are set as the output patterns, among the positions detected by the automatic positioning section.

3. The magnetic resonance imaging apparatus according to claim 2,
wherein the output pattern setting section generates an output pattern setting screen corresponding to the received examination part, displays the output pattern setting screen on the display device, and receives a setting of the output examination section through the output pattern setting screen.

4. The magnetic resonance imaging apparatus according to claim 2, further comprising:
a data storage unit that stores selectable examination sections as output patterns in advance for each examination part,
wherein the output pattern setting section receives the setting of the output examination section by receiving a selection from the output patterns stored in the data storage unit.

5. The magnetic resonance imaging apparatus according to claim 2,
wherein each examination section includes one or more slices, and
the detection result display section displays an outer frame of a range, which is specified by all slices of each of the examination sections that are output, as the stack.

6. The magnetic resonance imaging apparatus according to claim 1,
wherein the detection result display section displays the stack so as to blink.

7. The magnetic resonance imaging apparatus according to claim 1,
wherein the detection result display section switches display and non-display of the stack according to an instruction from an operator or at time intervals set in advance.

8. The magnetic resonance imaging apparatus according to claim 2,
wherein there is a plurality of examination sections set as the output patterns, and
the detection result display section displays the stack in a different display form for each examination section.

9. The magnetic resonance imaging apparatus according to claim 1,
wherein the detection result display section includes a selection receiving section that receives a selection of a position set as the imaging position.

10. The magnetic resonance imaging apparatus according to claim 9, further comprising:
an input device that receives an input from an operator,
wherein the detection result display section performs a simple display at a position, which is detected by the automatic positioning section, on the scanogram image,
the selection receiving section receives a selection of the position by receiving a selection of the simple display through the input device, and
the simple display is a display in which there is no interference with visibility of the scanogram image and a position and an inclination of the detected examination section are understandable.

11. The magnetic resonance imaging apparatus according to claim 10,
wherein the imaging position setting unit further includes an output pattern setting section that sets the examination sections, which are set as the imaging positions, as output patterns,
the detection result display section performs a simple display at a position of an examination section set as the output pattern, among the positions detected by the automatic positioning section, on the scanogram image,
the selection receiving section receives a selection of the position by receiving a selection of the simple display through the input device, and
the simple display is a display in which there is no interference with visibility of the scanogram image and the position and the inclination of the detected examination section are understandable.

12. The magnetic resonance imaging apparatus according to claim 9, further comprising:
an input device that receives an input from an operator,
wherein the selection receiving section receives a selection of a region on the scanogram image through the input device and sets a position within the selected region, among the positions detected by the automatic positioning section, as the selected position.

13. The magnetic resonance imaging apparatus according to claim 12,
wherein the imaging position setting unit further includes an output pattern setting section that sets the examination section, which is set as the imaging position, as an output pattern, and
the selection receiving section receives a selection of a region on the scanogram image through the input device and sets a position within the selected region, which is a position of the examination section set as the output pattern among the positions detected by the automatic positioning section, as the selected position.

14. The magnetic resonance imaging apparatus according to claim 1,
wherein the imaging position setting unit further includes an adjustment section that adjusts the imaging position set by the detection result display section, and
the imaging unit images the imaging position after the adjustment.

15. The magnetic resonance imaging apparatus according to claim 14,
wherein the adjustment section displays adjustment instruction buttons, which are used for adjustment of the imaging position, on the display device together with the stack displayed by the detection result display section and receives an adjustment of the imaging position through the adjustment instruction buttons.

16. The magnetic resonance imaging apparatus according to claim 14, further comprising:
an input device that receives an instruction from an operator,
wherein the adjustment section performs an adjustment by updating at least one of a display position of the stack and the number of stacks according to an instruction from the operator with respect to the stack through the input device.

17. The magnetic resonance imaging apparatus according to claim 14,
wherein each of the examination sections includes one or more slices, and
the adjustment section receives a change of the number of slices of the examination section according to an instruction from the operator with respect to the stack.

18. The magnetic resonance imaging apparatus according to claim 15,
wherein the adjustment instruction buttons include a button for giving an instruction regarding a movement direction of the stack selected by the operator and a button for giving an instruction regarding an arrangement of the stack selected by the operator.

19. An imaging position setting assisting method for assisting a setting of an imaging position of an examination part having a plurality of examination sections in a magnetic resonance imaging apparatus including a control processing system that performs calculation and control of an operation of the entire apparatus, the method comprising:
automatic positioning in which the control processing system detects positions of all examination sections of the examination part on a scanogram age acquired in advance; and
detection result display in which the control processing system sets one or more positions, which are determined in advance among the detected positions, as the imaging positions, and displays a stack at the imaging position of the scanogram image.
